(19) United States
(12) Patent Application Publication
(10) Pub. No.: US 2013/0083254 A1
(43) Pub. Date: Apr. 4, 2013

(54) TELEVISION AND ELECTRONIC APPARATUS

(71) Applicants: Mitsuhiro MURAKAMI, Tachikawa-shi (JP); Naohiro YOKOYAMA, Akishima-shi (JP)

(72) Inventors: Mitsuhiro MURAKAMI, Tachikawa-shi (JP); Naohiro YOKOYAMA, Akishima-shi (JP)

(73) Assignee: KABUSHIKI KAISHA TOSHIBA, Tokyo (JP)

(21) Appl. No.: 13/527,943

(22) Filed: Jun. 20, 2012

(30) Foreign Application Priority Data
Sep. 29, 2011 (JP) 2011-215147

(51) Int. Cl. H04N 5/64; H05K 7/02

(52) U.S. Cl. 348/836; 361/679.01; 348/E05.128

(57) ABSTRACT

According to one embodiment, an electronic apparatus includes a housing and a display. The housing includes a first end, a second end, and a wall between the first end and the second end. The second end is thicker than the first end. The wall includes an opening. The display is in the housing. The display includes an input receiving portion and is exposed through the opening.

### CROSS-REFERENCE TO RELATED APPLICATIONS

This application is based upon and claims the benefit of priority from prior Japanese Patent Application No. 2011-215147, filed Sep. 29, 2011; the entire contents of which are incorporated herein by reference.

### FIELD

Embodiments described herein relate generally to electronic apparatuses including televisions.

### BACKGROUND

A mobile electronic apparatus has been proposed which has a grip structure such that the user can hold and operate the mobile electronic apparatus with one hand.

### BRIEF DESCRIPTION OF THE DRAWINGS

A general architecture that implements the various features of the embodiments will now be described with reference to the drawings. The drawings and the associated descriptions are provided to illustrate the embodiments and not to limit the scope of the invention.

FIG. 1 is an exemplary perspective view of a television according to a first embodiment;

FIG. 2 is an exemplary perspective view of the television illustrated in FIG. 1;

FIG. 3 is an exemplary perspective view of a display unit illustrated in FIG. 2;

FIG. 4 is an exemplary perspective view of a portion of a stand illustrated in FIG. 2;

FIG. 5 is an exemplary perspective view of an electronic apparatus according to a second embodiment;

FIG. 6 is an exemplary side view of the electronic apparatus illustrated in FIG. 5;

FIG. 7 is an exemplary perspective view of the lower surface of the electronic apparatus illustrated in FIG. 5;

FIG. 8 is an exemplary perspective view of the electronic apparatus illustrated in FIG. 5;

FIG. 9 is an exemplary exploded perspective view of the electronic apparatus illustrated in FIG. 5;

FIG. 10 is an exemplary perspective view of the inside of the electronic apparatus illustrated in FIG. 5;

FIG. 11 is an exemplary plan view of the inside of the electronic apparatus illustrated in FIG. 5;

FIG. 12 is an exemplary perspective view of a module illustrated in FIG. 10;

FIG. 13 is an exemplary plan view of the module illustrated in FIG. 12;

FIG. 14 is an exemplary bottom view of the module illustrated in FIG. 12;

FIG. 15 is an exemplary front view of the module illustrated in FIG. 12;

FIG. 16 is an exemplary side view of the module illustrated in FIG. 12;

FIG. 17 is an exemplary enlarged perspective view of a portion of the rear end of the electronic apparatus illustrated in FIG. 5;

FIG. 18 is an exemplary cross-sectional view of the rear end of the electronic apparatus illustrated in FIG. 5;

FIG. 19 is an exemplary perspective view of a battery illustrated in FIG. 9;

FIG. 20 is an exemplary cross-sectional view of the rear end of the electronic apparatus illustrated in FIG. 5;

FIG. 21 is an exemplary perspective view of a middle plate illustrated in FIG. 9;

FIG. 22 is an exemplary plan view of the inside of the electronic apparatus illustrated in FIG. 5;

FIG. 23 is an exemplary cross-sectional view of the electronic apparatus illustrated in FIG. 5;

FIG. 24 is an exemplary enlarged perspective view of a portion of the rear end of the electronic apparatus illustrated in FIG. 5;

FIG. 25 is an exemplary enlarged perspective view of a portion of the rear end of the electronic apparatus illustrated in FIG. 5;

FIG. 26 is an exemplary cross-sectional view of the front end of the electronic apparatus illustrated in FIG. 5;

FIG. 27 is an exemplary cross-sectional view of the rear end of the electronic apparatus illustrated in FIG. 5;

FIG. 28 is an exemplary perspective view of a locking mechanism of a power button of the electronic apparatus illustrated in FIG. 5;

FIG. 29 is an exemplary cross-sectional view of the locking mechanism of the power button of the electronic apparatus illustrated in FIG. 5;

FIG. 30 is an exemplary cross-sectional view of a cover of a connector of the electronic apparatus illustrated in FIG. 5;

FIG. 31 is an exemplary cross-sectional view of a cover of a connector of the electronic apparatus illustrated in FIG. 5;

FIG. 32 is an exemplary cross-sectional view of a power connector of the electronic apparatus illustrated in FIG. 5;

FIG. 33 is an exemplary cross-sectional view of a power connector of the electronic apparatus illustrated in FIG. 5;

FIG. 34 is an exemplary perspective view of a dock to which the electronic apparatus illustrated in FIG. 5 can be attached;

FIG. 35 is an exemplary perspective view of the dock illustrated in FIG. 34;

FIG. 36 is an exemplary perspective view of a second connector illustrated in FIG. 34;

FIG. 37 is an exemplary perspective view of a state in which the electronic apparatus is attached to the dock illustrated in FIG. 34;

FIG. 38 is an exemplary side view of the dock and the electronic apparatus illustrated in FIG. 37;

FIG. 39 is an exemplary cross-sectional view of the dock and the electronic apparatus illustrated in FIG. 37 taken along the line F39-F39;

FIG. 40 is an exemplary cross-sectional view of the dock and the electronic apparatus illustrated in FIG. 37 taken along the line F40-F40;

FIG. 41 is an exemplary perspective view of the inside of the dock illustrated in FIG. 34;

FIG. 42 is an exemplary perspective view of a supporting mechanism of the second connector illustrated in FIG. 41;

FIG. 43 is an exemplary plan view of the supporting mechanism of the second connector illustrated in FIG. 41;

FIG. 44 is an exemplary perspective view of the supporting mechanism of the second connector illustrated in FIG. 41;

FIG. 45 is an exemplary cross-sectional view of the supporting mechanism of the second connector illustrated in FIG. 41;

FIG. 46 is an exemplary cross-sectional view of a modification of the supporting mechanism of the second connector illustrated in FIG. 41;

FIG. 47 is an exemplary perspective view of the dock and the electronic apparatus illustrated in FIG. 37;

FIG. 48 is an exemplary perspective view of the dock and the electronic apparatus illustrated in FIG. 37;

FIG. 49 is an exemplary cross-sectional view of the dock and the electronic apparatus illustrated in FIG. 37; and

FIG. 50 is an exemplary cross-sectional view of a modification of the dock and the electronic apparatus illustrated in FIG. 37.

### DETAILED DESCRIPTION

Various embodiments will be described hereinafter with reference to the accompanying drawings.

In general, according to one embodiment, an electronic apparatus comprises a housing and a display. The housing comprises a first end, a second end, and a wall between the first end and the second end. The second end is thicker than the first end. The wall comprises an opening. The display is in the housing. The display comprises an input receiving portion and is exposed through the opening.

Hereinafter, embodiments will be described with reference to the drawings.

### First Embodiment

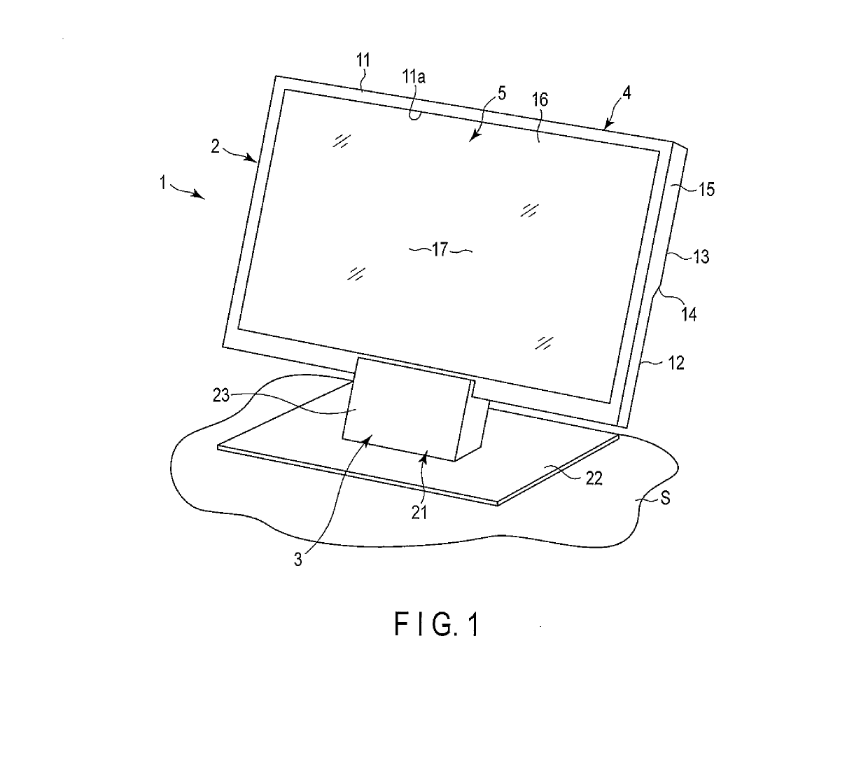

FIGS. 1 to 4 show a television 1 according to a first embodiment. The television 1 is an example of an “electronic apparatus”. As shown in FIG. 1, the television 1 includes a display unit 2 and a stand 3 supporting the display unit 2. The stand 3 is another example of the “electronic apparatus” and is also an example of a “supporting unit”, a “supporting portion”, a “stand”, a “connector”, or an “expansion unit”.

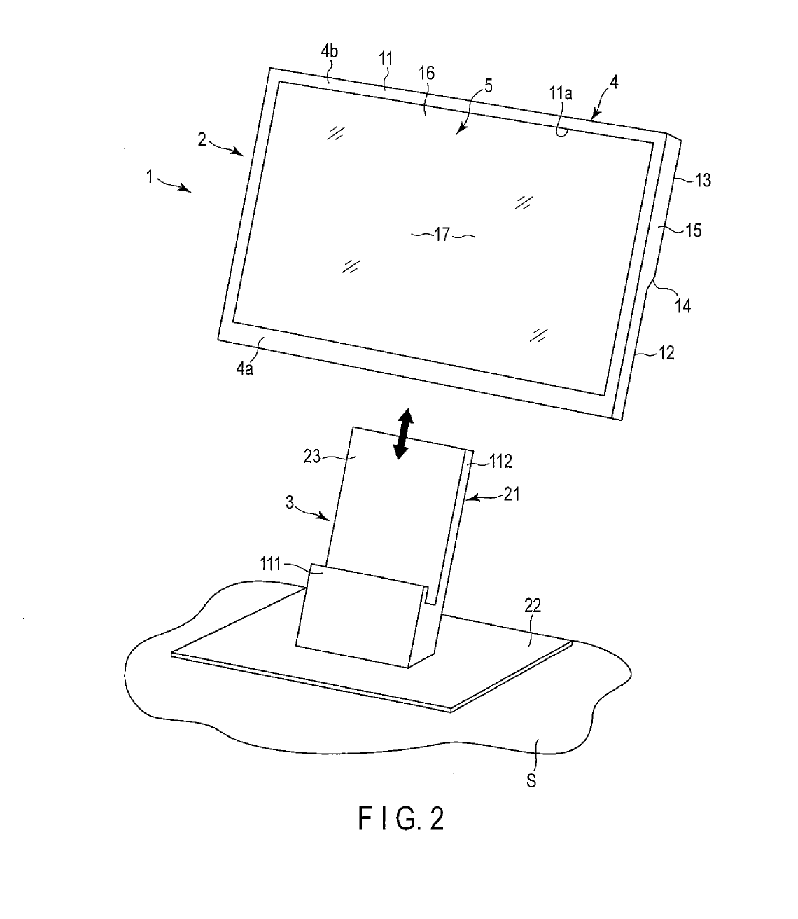

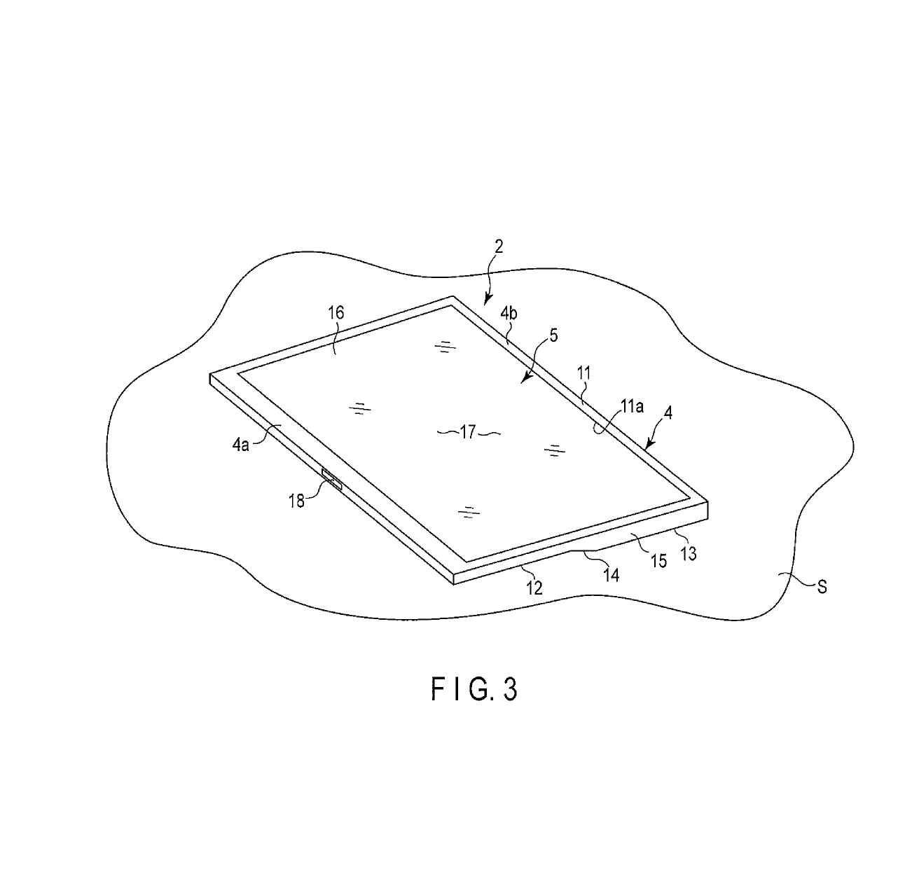

As shown in FIG. 2, the display unit 2 is removably supported by the stand 3. That is, the television 1 can be used in a first state (see FIG. 1) in which the display unit 2 is supported by the stand 3 and a second state (see FIG. 3) in which the display unit 2 is removed from the stand 3.

As shown in FIG. 1, the display unit 2 includes a first housing 4 and a display 5 which is accommodated in the first housing 4. The first housing 4 includes a front wall 11 (i.e., upper wall), a first rear wall 12 (i.e., first bottom wall), a second rear wall 13 (i.e., second bottom wall), an slope 14, and a circumferential wall 15. The front wall 11 is an example of a “wall” or a “wall portion”. The display 5 includes a display screen 17 provided with a touch sensor 16. The front wall 11 of the first housing 4 includes an opening 11a through which the display screen 17 is exposed.

As shown in FIG. 3, the display unit 2 is removed from the stand 3, is directly placed on a mounting surface S (i.e., outer mounting surface, or e.g., the upper surface of a desk), and can be used. A first connector 18 is provided at the front end of the display unit 2.

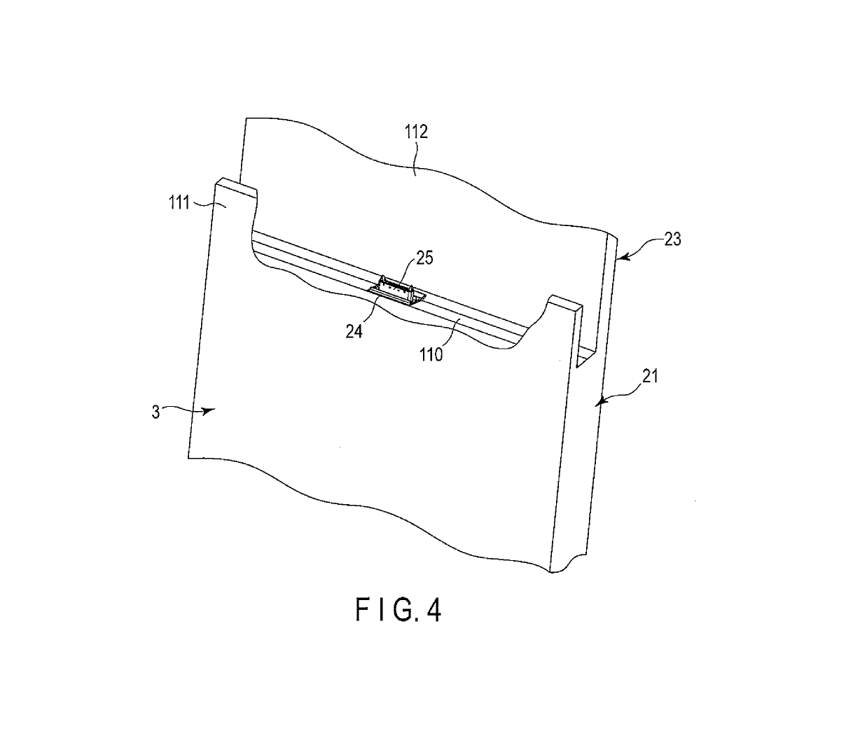

As shown in FIG. 2, the stand 3 includes a second housing 21. The second housing 21 includes a bottom wall 22 and a holder 23. The holder 23 is an example of a “holding portion”. As shown in FIG. 4, the holder 23 includes an opening 24. A second connector 25 configured to connect to the display unit 2 (i.e., first connector 18) is provided in the opening 24. The second connector 25 is supported by the same structure as that in a second embodiment, which will be described below, so as to be movable.

The details of the display unit 2 are substantially the same as those in an electronic apparatus 31 according to the second embodiment. The details of the stand 3 are substantially the same as those of a dock 32 according to the second embodiment. Therefore, the second embodiment will be described as a representative example and the detailed description thereof will not be repeated in this embodiment.

### Second Embodiment

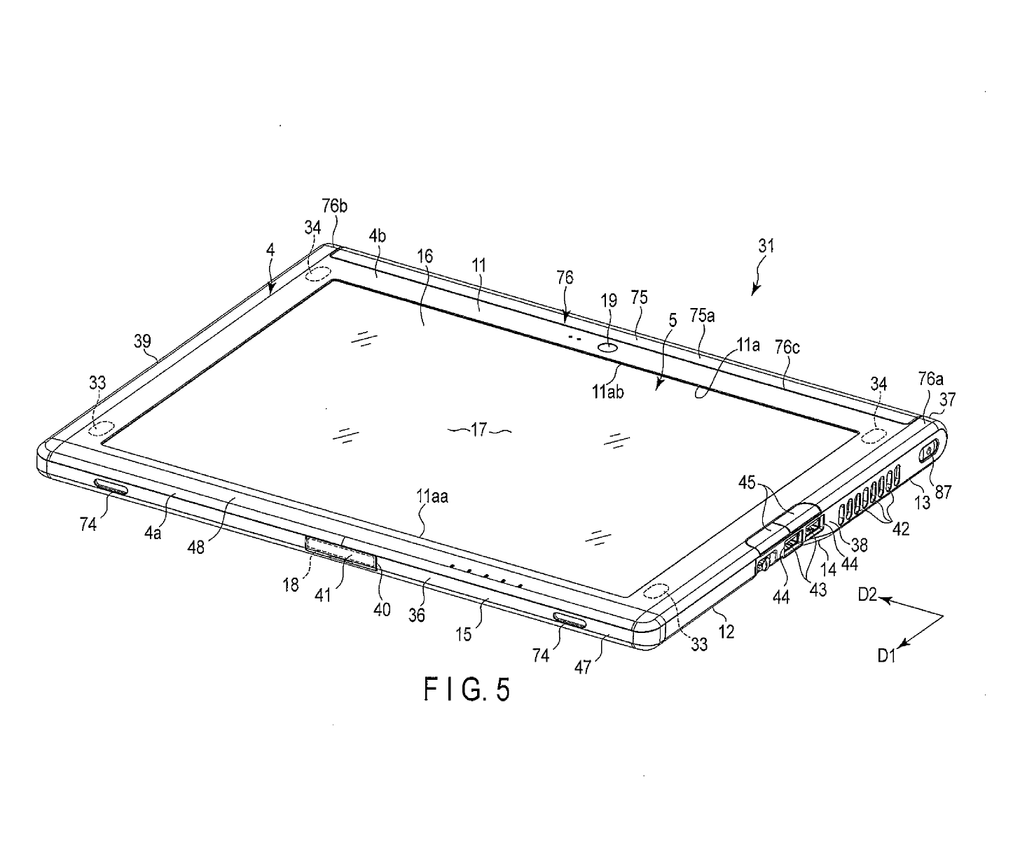

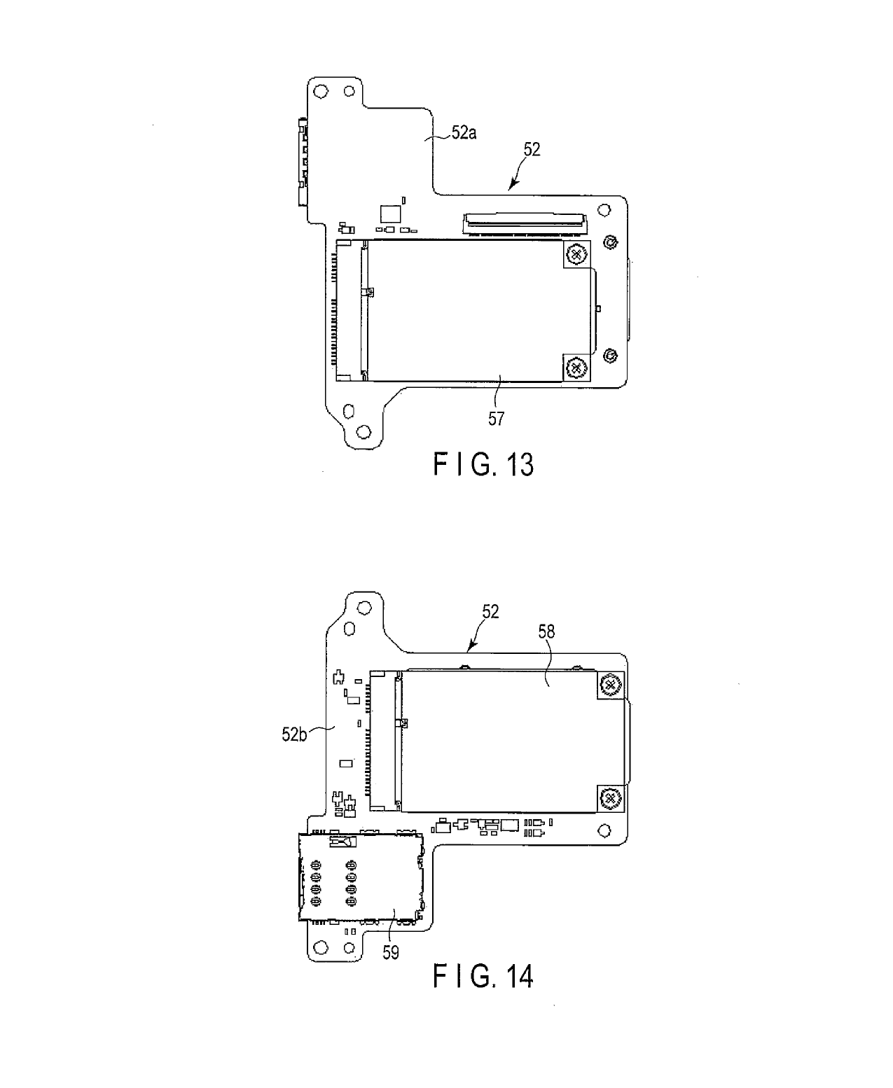

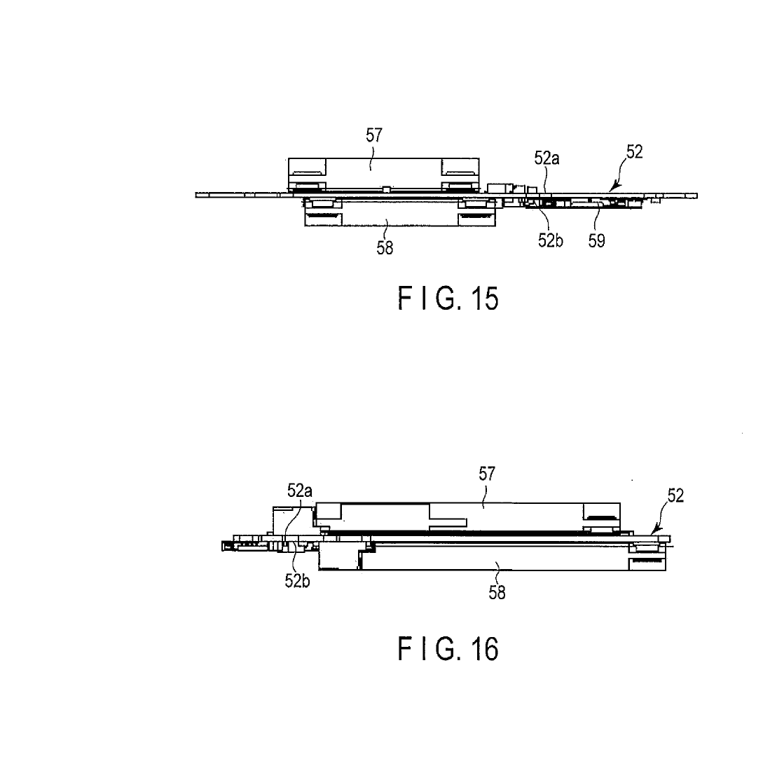

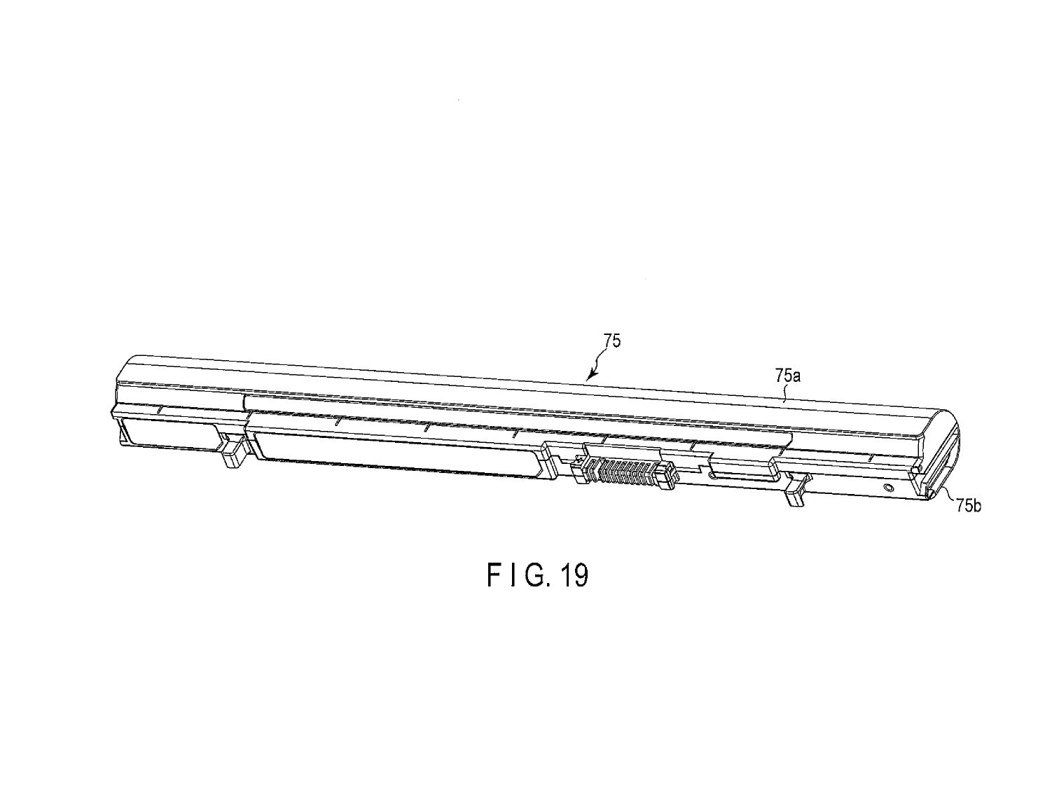

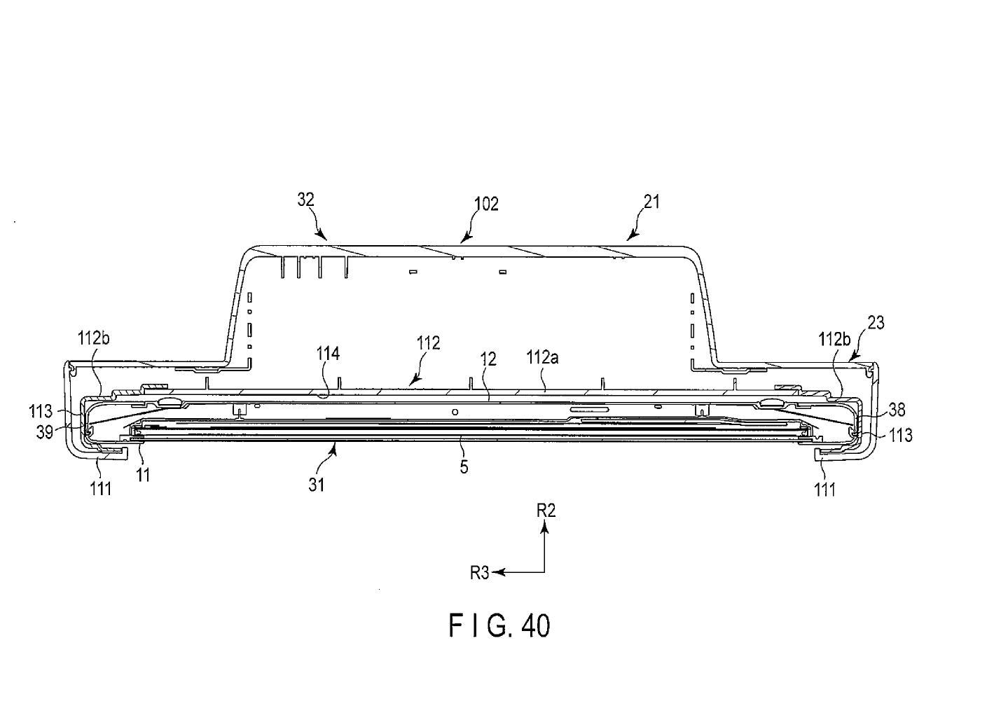

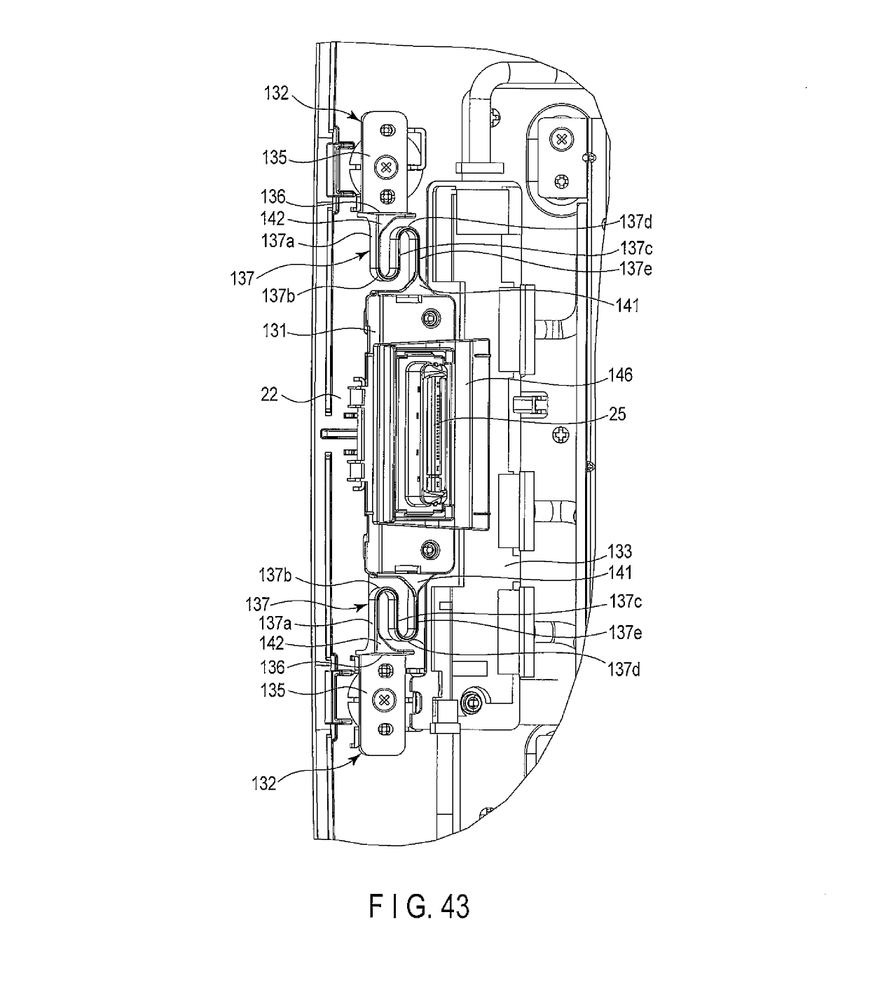

Next, an electronic apparatus 31 according to a second embodiment will be described with reference to FIGS. 5 to 50. The electronic apparatus 31 is, for example, a slate portable computer (hereinafter, referred to as a slate PC) and is a so-called tablet PC (i.e., tablet terminal). The electronic apparatus to which this embodiment can be applied is not limited to the above-mentioned example. This embodiment can be widely applied to, for example, mobile phones including smart phones, e-book readers, and other electronic apparatuses. The electronic apparatus 31 is an example of a “display unit”.

As shown in FIGS. 5 to 8, the electronic apparatus 31 includes a housing 4. The housing 4 is an example of a “first housing”. The housing 4 has, for example, a flat box shape. The housing 4 includes a first end 4a and a second end 4b. The first end 4a is, for example, a front end. The second end 4b is, for example, a rear end and is opposite to the first end 4a. In the specification, the side close to the user is defined as the “front side” and the side away from the user is defined as the “rear side”. In addition, the left and right sides are defined, as viewed from the user.

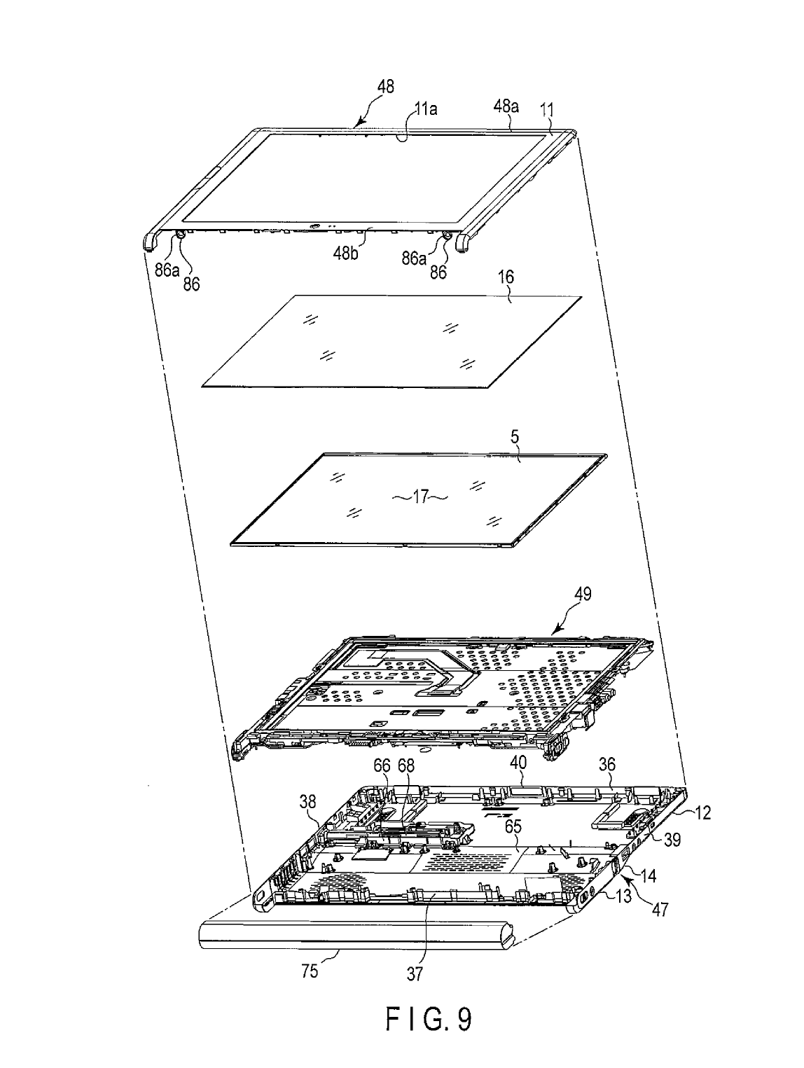

As shown in FIG. 9, a display 5 is provided in the housing 4. The display 5 includes a display screen 17. The display screen 17 is provided with a touch sensor 16 (i.e., touch panel). The touch sensor 16 overlaps the display screen 17 and is formed integrally with the display screen 17. In this way, the electronic apparatus 31 can receive an input from the user. The touch sensor 16 is an example of an “input unit (i.e., input receiving unit)”. An example of the display 5 is a liquid crystal display panel, but the display 5 is not limited thereto.

Next, the structure of each component of the electronic apparatus 31 will be described in detail.

(Wedge Sharp of Housing)

As shown in FIGS. 5 to 8, the housing 4 includes an upper wall 11 (i.e., front wall), a first bottom wall 12 (i.e., first rear wall), a second bottom wall 13 (i.e., second rear wall), an slope 14, and a circumferential wall 15. The upper wall 11 is an example of a “wall” or a “wall portion”. The upper wall 11 extends substantially in parallel to the display screen 17 and has a planar shape. The upper wall 11 extends between the first end 4a and the second end 4b.

The upper wall 11 includes an opening 11a through which the display screen 17 is exposed to the outside. The upper wall 11 is relatively thin. Therefore, the surface of the upper wall 11 and the display screen 17 are disposed substantially on the same plane. The upper wall 11 is an example of a “first surface” or a “first wall” from which the display screen 17 is exposed.

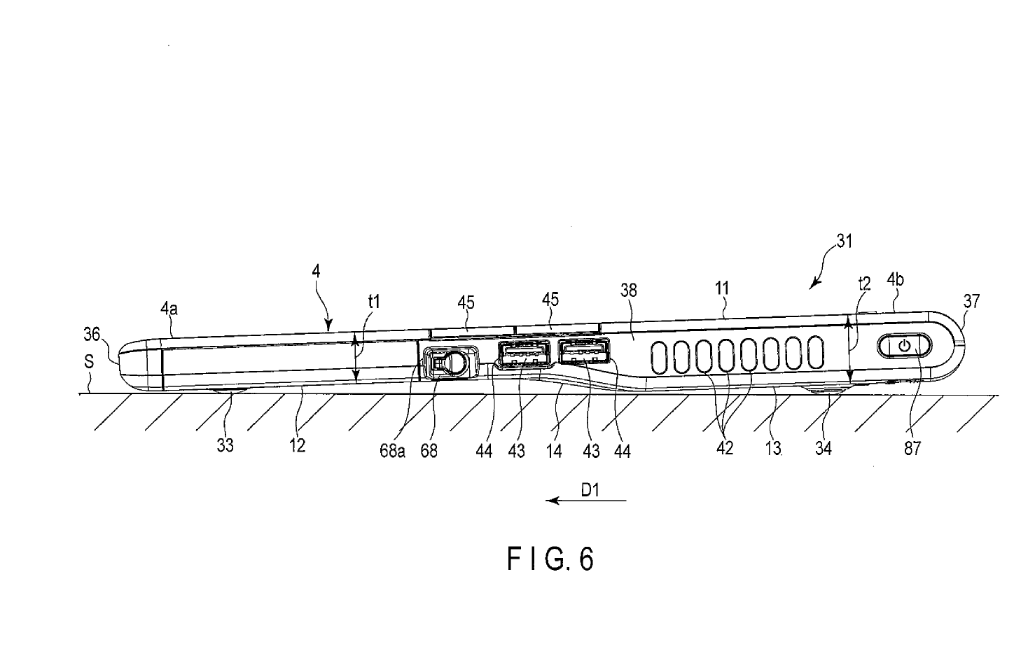

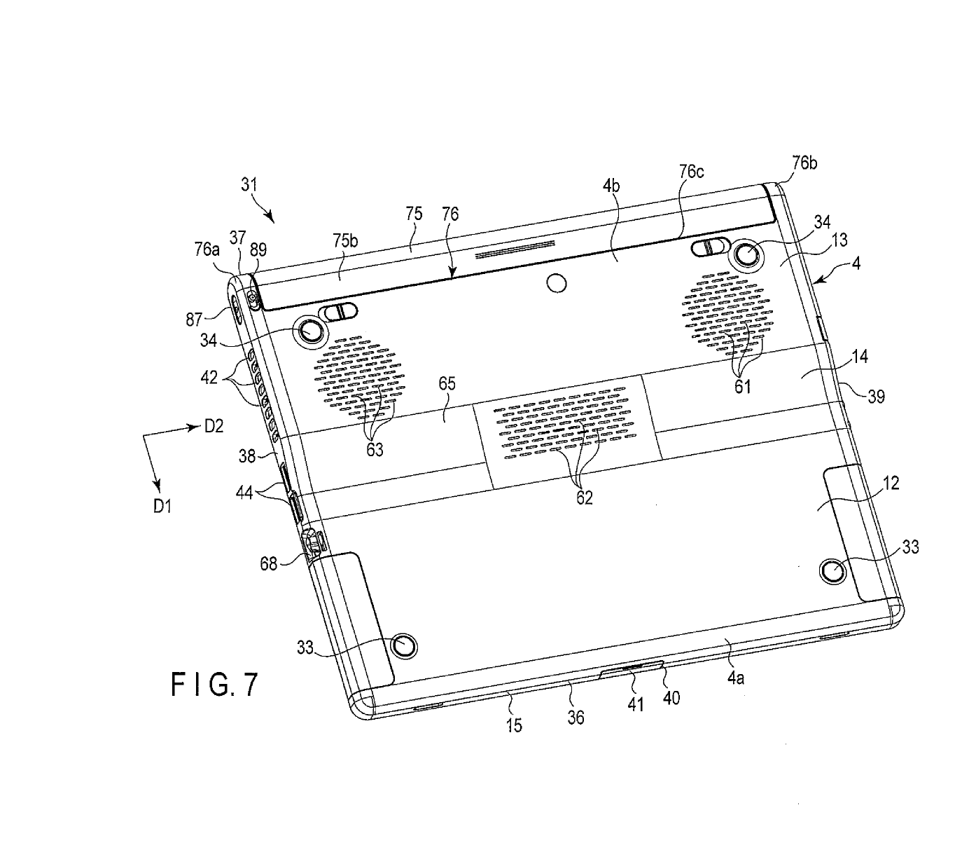

As shown in FIG. 6, the first bottom wall 12, the second bottom wall 13, and the slope 14 are opposite to the upper wall 11. That is, the first bottom wall 12, the second bottom wall 13, and the slope 14 face the display 5 from the side opposite to the upper wall 11. Each of the first bottom wall 12, the second bottom wall 13, and the slope 14 is an example of a “second surface” or a “second wall”. As shown in FIG. 7, each of the first bottom wall 12, the second bottom wall 13, and the slope 14 extends over the entire width of the housing 4 in the longitudinal direction (i.e., width direction) of the housing 4.

As shown in FIG. 6, the first bottom wall 12 is adjacent to the first end 4a of the housing 4 and forms a portion of the first end 4a. The first bottom wall 12 extends substantially in parallel to the display screen 17. The distance between the first bottom wall 12 and the display screen 17 is a first distance t1. The first distance t1 is a width in the thickness direction of the housing 4 and is an example of a “first width” or a “first thickness”. The first bottom wall 12 includes a plurality of first legs 33 (i.e., supporting legs, leg portions, or supporting portions). The first bottom wall 12 is supported by the first legs 33.

The second bottom wall 13 is adjacent to the second end 4b of the housing 4 and forms a portion of the second end 4b. The second bottom wall 13 extends substantially in parallel to the display screen 17. The distance between the second bottom wall 13 and the display screen 17 is a second distance t2. The second distance t2 is a width in the thickness direction of the housing 4 and is an example of a “second width” or a “second thickness”. The second distance t2 is greater than the first distance t1. The second bottom wall 13 includes a plurality of second legs 34 (i.e., supporting legs, leg portions, or supporting portions). The second bottom wall 13 is supported by the second legs 34. The second leg 34 is higher (i.e., thicker) than the first leg 33.

As shown in FIG. 6, the slope 14 (i.e., inclined wall or inclined portion) is disposed between the first bottom wall 12 and the second bottom wall 13 and extends between the first bottom wall 12 and the second bottom wall 13. That is, the slope 14 connects the rear end of the first bottom wall 12 and the front end of the second bottom wall 13. The slope 14 is inclined with respect to the display screen 17. The slope 14 is inclined from the first bottom wall 12 to the second bottom wall 13 in a direction in which it is separated from the display screen 17, and smoothly connects the first bottom wall 12 and the second bottom wall 13.

As described above, the second bottom wall 13 is further away from the upper wall 11 (i.e., display screen 17) than the first bottom wall 12. That is, the second end 4b of the housing 4 is thicker than the first end 4a. The slope 14 which smoothly connects the first bottom wall 12 and the second bottom wall 13 is provided therebetween. In this way, the housing 4 is formed in a wedge shape.

As shown in FIG. 6, the upper wall 11 (i.e., display screen 17) is inclined upward with respect to the mounting surface S, with the first legs 33 and the second legs 34 being placed on (i.e., coming into contact with) the mounting surface S. In this embodiment, the upper wall 11 (i.e., display screen 17) is inclined at an angle of about 5 degrees with respect to the mounting surface S. The first bottom wall 12 and the second bottom wall 13 are supported by the first legs 33 and the second legs 34 and are inclined upward with respect to the mounting surface S so as to be separated from the mounting surface S.

The slope 14 is closer to the upper wall 11 than a line (i.e., virtual line) connecting the first leg 33 and the second leg 34. In this way, the slope 14 is separated from the mounting surface S, with the first legs 33 and the second legs 34 being placed on (coming into contact with) the mounting surface S.

As shown in FIG. 5, the opening 11a includes a first edge 11aa and a second edge 11ab. The first edge 11aa is, for example, a front edge. The first edge 11aa extends along the first end 4a of the housing 4. The second edge 11ab is, for example, a rear edge and is opposite to the first edge 11aa. The second edge 11ab extends along the second end 4b of the housing 4.

In a plan view, at least a portion of the second leg 34 is further away from the first leg 33 than the second edge 11ab of the opening 11a. That is, at least a portion of the second leg 34 is disposed on the rear side of the second edge 11ab of the opening 11a. In other words, the second edge 11ab of the opening 11a is disposed between at least a portion of the second leg 34 and the first leg 33. Therefore, the balance of the electronic apparatus 31 is less likely to be broken, regardless of the position of the display screen 17 (i.e., touch sensor 16) pressed by the user.

As shown in FIGS. 5 to 8, the circumferential wall 15 extends in a direction crossing (for example, a direction substantially perpendicular to) the upper wall 11 and connects the upper wall 11, the first bottom wall 12, the second bottom wall 13, and the slope 14. The circumferential wall 15 includes a front wall 36, a rear wall 37, a first side wall 38 (e.g., right wall), and a second side wall 39 (e.g., left wall).

The front wall 36 is disposed at the first end 4a of the housing 4 and extends in the longitudinal direction of the housing 4. The rear wall 37 is opposite to the front wall 36 and extends substantially in parallel to the front wall 36. The first side wall 38 and the second side wall 39 extend in a direction crossing (for example, a direction substantially perpendicular to) the front wall 36 and the rear wall 37 and connect the front wall 36 and the rear wall 37.

As shown in FIG. 5, the first connector 18 is provided at the first end 4a of the housing 4. Specifically, an opening 40 is provided in the front wall 36. The first connector 18 is provided in the opening 40. The first connector 18 is a docking connector configured to connect to a dock 32, which will be described below, and is an example of a battery connector. In addition, a cover 41 is removably attached to the opening 40. A camera 19 is provided at the second end 4b.

As shown in FIG. 6, for example, a plurality of exhaust holes 42 (i.e., openings) are provided in the first side wall 38. The exhaust holes 42 are disposed between the upper wall 11 and the second bottom wall 13. In addition, a plurality of connectors 43 and a plurality of openings 44 corresponding to the connectors 43 are provided in the first side wall 38. The connectors 43 are accommodated in the housing 4 and are exposed to the outside of the housing 4 through the openings 44. An example of the connector 43 is a universal serial bus (USB), but the connector 43 is not limited thereto.

As shown in FIG. 6, one of the connectors 43 is disposed between the upper wall 11 and the slope 14. The connector 43 is disposed closer to the upper wall 11 (i.e., display screen 17) than to the slope 14. That is, the distance between the connector 43 and the upper wall 11 is less than the distance between the connector 43 and the slope 14. In this way, when the electronic apparatus 31 is placed on the mounting surface S, the connector 43 is disposed at a position that is relatively high from the mounting surface S, which makes it easy for the user to use the electronic apparatus 31. As shown in FIG. 5, mechanical switches 45 are provided above the connectors 43.

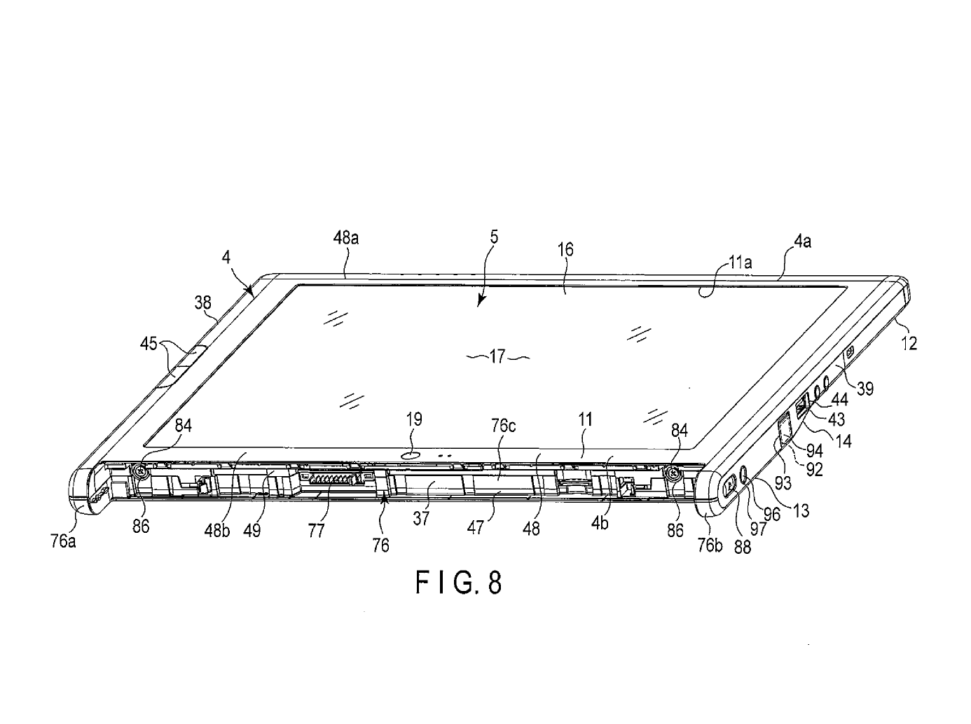

As shown in FIG. 8, the connector 43 and an opening 44 corresponding to the connector 43 are provided in the second side wall 39, similarly to the first side wall 38. The connector 43 is disposed between the upper wall 11 and the slope 14. The connector 43 is disposed closer to the upper wall 11 (i.e., display screen 17) than to the slope 14.

Next, the internal structure of the housing will be described.

As shown in FIG. 9, the housing 4 includes a base 47 (i.e., a lower cover or a first member) and a mask 48 (i.e., an upper cover or a second member). The base 47 includes the first bottom wall 12, the second bottom wall 13, the slope 14, the front wall 36, the rear wall 37, the first side wall 38, and the second side wall 39 and has a bowl shape with the top open. The base 47 is made of, for example, a metal material and gives strength to the housing 4. The mask 48 includes the upper wall 11. The mask 48 is a bezel member covering the display 5 and is relatively thin. The mask 48 may be made of a metal material or plastic.

The touch sensor 16, the display 5, and a middle plate 49 (i.e., a middle base or a middle frame) are provided between the base 47 and the mask 48. The middle plate 49 is an example of a reinforcing member and is made of, for example, a metal material. The strength of the housing 4 is ensured by the middle plate 49 and the base 47. A recess corresponding to the display 5 is provided in the upper surface of the middle plate 49.

The display 5 and the touch sensor 16 are supported by the middle plate 49 and the mask 48. In this embodiment, the display 5 and the touch sensor 16 are not fixed by screws. The mask 48 is fixed to the middle plate 49 with the display 5 and the touch sensor 16 interposed therebetween. In this way, the display 5 and the touch sensor 16 are held between the mask 48 and the middle plate 49.

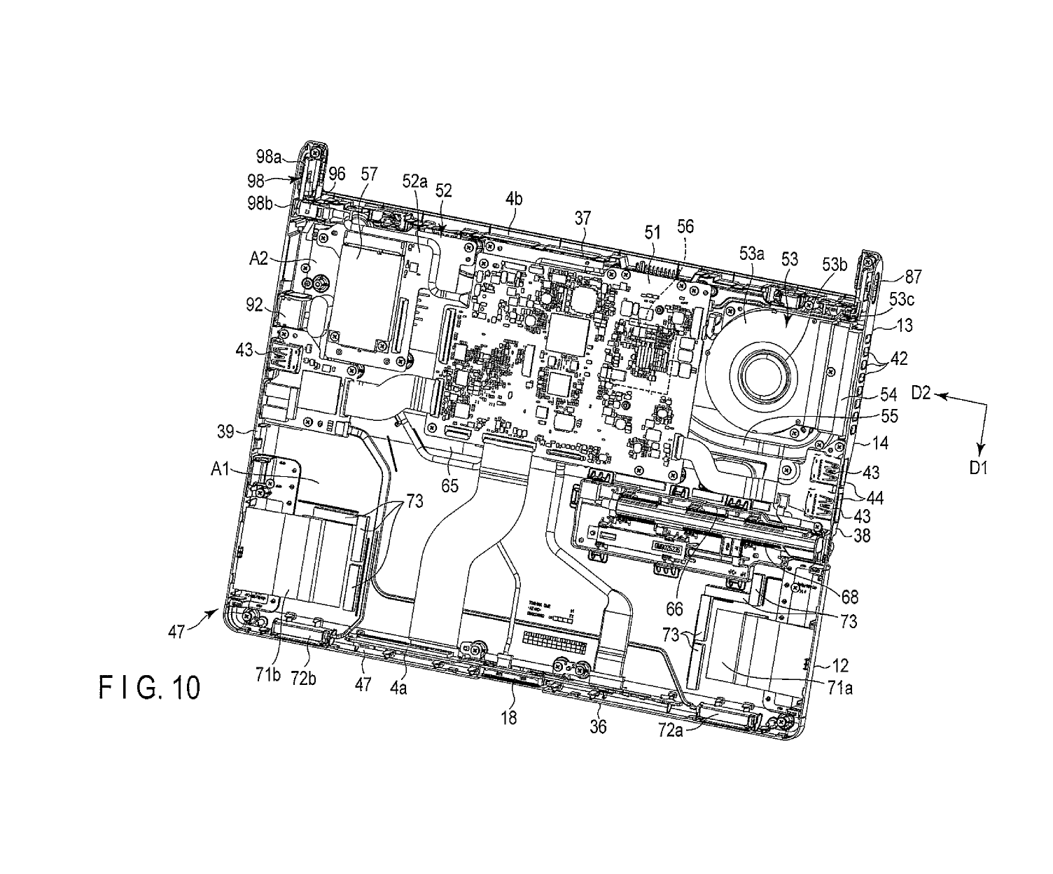

As shown in FIGS. 10 and 11, the housing 4 includes a first board 51 (i.e., first circuit board), a second board 52 (i.e., second circuit board), a fan 53, a heat sink 54, and a heat pipe 55. The first board 51, the second board 52, the fan 53, the heat sink 54, and the heat pipe 55 are provided between the base 47 and the middle plate 49.

The first board 51 is, for example, a main board and is electrically connected to the display 5. The first board 51 is provided outside the first bottom wall 12 and faces the second bottom wall 13 and the slope 14. That is, a portion of the first board 51 is disposed between the display 5 and the second bottom wall 13. The first board 51 is provided substantially at the center of the housing 4 in the longitudinal direction of the housing 4.

A heat-generating component 56 is mounted on the lower surface of the first board 51. An example of the heat-generating component 56 is a central processing unit (CPU), but the heat-generating component 56 is not limited thereto. The heat-generating component 56 may be various kinds of components requiring heat dissipation. The heat-generating component 56 is disposed between the display 5 and the second bottom wall 13.

As shown in FIGS. 10 and 11, the heat sink 54 faces the exhaust holes 42. The heat sink 54 is, for example, a fin unit including a plurality of fins. The heat pipe 55 extends between the heat-generating component 56 and the heat sink 54 and thermally connects the heat-generating component 56 and the heat sink 54.

The fan 53 is disposed between the first board 51 and the heat sink 54. That is, the fan 53 is disposed between the display 5 and the second bottom wall 13. The fan 53 includes a first surface (not shown) which faces the second bottom wall 13 and a second surface 53a which is opposite to the first surface and faces the display 5 (i.e., upper wall 11).

The fan 53 is a centrifugal type and includes air intakes 53b provided in each of the first surface and the second surface 53a. The fan 53 includes a discharge hole 53c (i.e., outlet) facing the heat sink 54. The fan 53 draws air from the air intake 53b and blows air from the discharge hole 53c to the heat sink 54. In this way, the heat dissipation of the heat-generating component 56 is accelerated.

The second board 52 is disposed on the side of the first board 51 opposite to the fan 53. That is, the first board 51 is disposed between the second board 52 and the fan 53. In other words, the second board 52 and the fan 53 are disposed on both sides of the first board 51 in the longitudinal direction of the housing 4. The second board 52 is electrically connected to the first board 51. The second board 52 is an example of a “module”. The “module” is not limited to the board, but may be other components. The second board 52 is disposed between the display 5 and the second bottom wall 13.

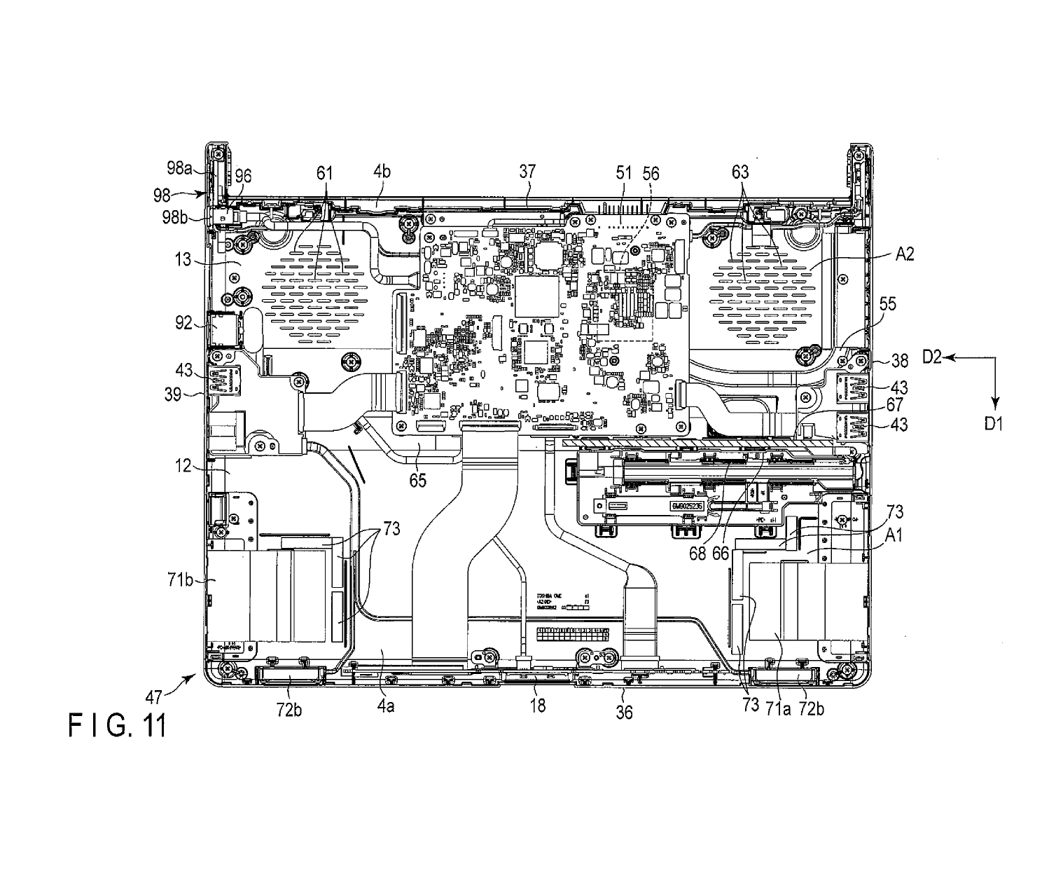

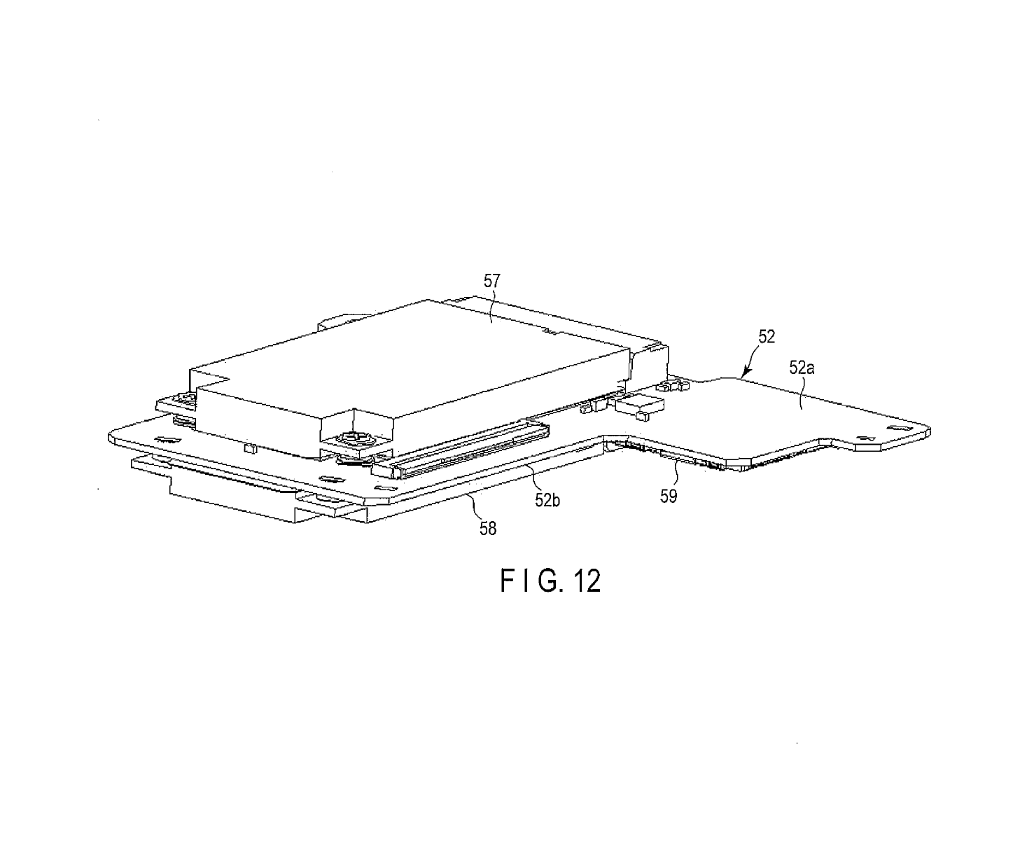

FIGS. 12 to 16 show the second board 52. The second board 52 includes a first surface 52a which faces the second bottom wall 13 and a second surface 52b which is opposite to the first surface 52a and faces the display 5 (i.e., upper wall 11).

A storage module 57 (i.e., a storage device or a storage medium) is mounted on the first surface 52a. The storage module 57 is an example of a “first component” and is, for example, a small solid state drive (SSD). An antenna module 58 is mounted on the second surface 52b. The antenna module 58 is an example of a “second component” and is, for example, a third-generation mobile telecommunication (3G) module.

The storage module 57 and the antenna module 58 are, for example, card modules with the same size and are separately mounted on the front and rear surfaces of the second board 52. The storage module 57 and the antenna module 58 overlap each other in a plan view of the second board 52. Each of the storage module 57 and the antenna module 58 has a rectangular shape. The longitudinal direction of the storage module 57 is substantially aligned with the longitudinal direction of the antenna module 58. The “first component” and the “second component” are not limited to the above examples.

A card socket 59 is mounted on the first surface 52a of the second board 52. An example of the card socket 59 is a subscriber identity module (SIM) socket into which a SIM card is removably inserted.

As shown in FIGS. 10 and 11, the housing 4 is mainly divided into a first region A1 (i.e., first portion) and a second region A2 (i.e., second portion). The first region A1 includes the first bottom wall 12. That is, the first region A1 is a space between the first bottom wall 12 and the upper wall 11.

The second region A2 includes the second bottom wall 13 and the slope 14. That is, the second region A2 is a space between the upper wall 11, and the second bottom wall 13 and the slope 14. The first board 51, the second board 52, the fan 53, the heat sink 54, and the heat pipe 55 are mounted so as to be concentrated in the second region A2.

Next, a first direction D1 and a second direction D2 are defined. The first direction D1 is from the second bottom wall 13 to the first bottom wall 12. The second direction D2 is a direction crossing (for example, a direction perpendicular to) the first direction D1. The second direction D2 is from the first side wall 38 to the second side wall 39 and is aligned with the longitudinal direction of the housing 4. The exhaust hole 42, the heat sink 54, the fan 53, the first board 51, and the second board 52 of the housing 4 are arranged in the second direction D2.

As shown in FIGS. 7 and 11, the housing 4 includes first to third air inlets 61, 62, and 63 (i.e., openings). The first air inlets 61 and the third air inlets 63 are provided in the second bottom wall 13. The first air inlets 61 are provided at the left end of the housing 4 and face the second board 52. The third air inlets 63 are provided at the right end of the housing 4 and face the fan 53. The second air inlets 62 are provided in the slope 14. The second air inlets 62 are provided substantially at the center of the housing 4.

As described above, the first to third air inlets 61, 62, and 63 are separately provided in the second bottom wall 13 and the slope 14. In addition, the first to third air inlets 61, 62, and 63 are separately provided the right end, the center, and the left end of the housing 4. Therefore, when the user holds the housing 4 with the hands and uses it, all of the air inlets 61, 62, and 63 are less likely to be blocked by the hands of the user at the same time. As a result, the heat radiation performance of the electronic apparatus 31 can be maintained at high level.

The second bottom wall 13 and the slope 14 are inclined in different directions. Therefore, in the structure in which the first to third air inlets 61, 62, and 63 are separately provided in the second bottom wall 13 and the slope 14, even when the user places the electronic apparatus 31 on an object and uses it, all of the first to third air inlets 61, 62, and 63 are less likely to be blocked at the same time. As a result, the heat radiation performance of the electronic apparatus 31 can be maintained at high level.

As shown in FIGS. 10 and 11, the third air inlets 63 face the air intake 53b formed in the first surface of the fan 53. That is, the fan 53 draws relatively cold air from the third air inlets 63 through the air intake 53b formed in the first surface and blows the air to the heat sink 54.

The first air inlets 61 are disposed on the side of the first board 51 (i.e., heat-generating component 56) opposite to the fan 53. That is, the first board 51 (i.e., heat-generating component 56) is disposed between the first air inlets 61 and the fan 53 in the second direction D2. Air in the housing 4 is drawn through the air intake 53b formed in the second surface 53a of the fan 53. Therefore, when the fan 53 is driven, air is drawn from the first air inlets 61 to the inside of the housing 4.

In this way, the flow of air from the first air inlets 61 to the fan 53 occurs in the second region A2 of the housing 4. The outdoor air drawn from the first air inlets 61 to the fan 53 passes through the second board 52 and the first board 51 (i.e., heat-generating component 56) to take heat from the second board 52 and the first board 51 (i.e., heat-generating component 56). In this way, the heat radiation performance is improved.

Since the space of the second region A2 is thicker than that of the first region A1 in the housing 4, the air is more likely to flow in the second region A2 than that in the first region A1. In other words, since the first region A1 is thinner than the second region A2, the air is less likely to flow in the first region A1 than that in the second region A2. A step portion 65 is formed between the second region A2 and the first region A1 due to the difference in thickness between the second region A2 and the first region A1. The step portion 65 functions as a airflow shield which divides the internal space of the housing 4 into the first region A1 and the second region A2. In this way, an air current is likely to occur in a thick portion (i.e., second region A2) in the housing 4.

Specifically, as shown in FIGS. 7 and 11, the first to third air inlets 61, 62, and 63 are provided in the second region A2 of the housing 4. That is, the internal space of the housing 4 is divided into the second region A2 in which various kinds of components requiring heat radiation are mounted so as to be concentrated and air flows by the air inlets 61, 62, and 63, the exhaust holes 42, and the fan 53 and the first region A1 in which no main component is provided and there is little air flow.

As shown in FIG. 10, a airflow shield 66 is provided in the housing 4. The airflow shield 66 is, for example, a rib which protrudes from the inner surface of the housing 4. The airflow shield 66 is disposed between the first bottom wall 12 and the second bottom wall 13 and extends in the second direction D2. Specifically, the airflow shield 66 is disposed between the slope 14 and the first bottom wall 12. The airflow shield 66 at least partially divides the inner space of the housing 4 into the first region A1 comprising the first bottom wall 12 and the second region A2 comprising the second bottom wall 13, the exhaust holes 42, the fan 53, the heat-generating component 56, and the first to third air inlets 61, 62, and 63.

Another airflow shield 67 is provided on the lower surface of the middle plate 49. An example of the airflow shield 67 is a sponge member attached to the middle plate 49. The airflow shield 67 is interposed between the base 47 and the middle plate 49 and blocks the gap between the base 47 and the middle plate 49.

As shown in FIG. 11, specifically, the airflow shield 67 is disposed between the first bottom wall 12 and the second bottom wall 13 and extends in the second direction D2. The airflow shield 67 is disposed between the slope 14 and the first bottom wall 12. The airflow shield 67 at least partially devices the internal space of the housing 4 into the first region A1 comprising the first bottom wall 12 and the second region A2 comprising the second bottom wall 13, the exhaust holes 42, the fan 53, the heat-generating component 56, and the first to third air inlets 61, 62, and 63.

As shown in FIG. 11, the airflow shields 66 and 67 are adjacent to the first side wall 38. The airflow shields 66 and 67 are disposed between the fan 53 and the first bottom wall 12. The airflow shields 66 and 67 are, for example, partially provided in the housing 4. The airflow shields 66 and 67 extend from, for example, the first side wall 38 to the front side of the first board 51. The airflow shields 66 and 67 may be provided over the entire width of the housing 4 in the longitudinal direction.

The fan 53 is, for example, a centrifugal type and radially draws air. When the airflow shields 66 and 67 are provided between the fan 53 and the first bottom wall 12, it is difficult for the fan 53 to draw air from the first region A1. As a result, it is easy for the fan 53 to draw air from the second region A2 and it is easy for air to flow in the second region A2. Only one of the airflow shields 66 and 67 may be provided.

As shown in FIGS. 10 and 11, a pen accommodating portion 68 is provided adjacent to the first side wall 38. The pen accommodating portion 68 is provided along the airflow shields 66 and 67. In this way, members (e.g., the pen accommodating portion 68 and the airflow shields 66 and 67) with a relatively large length are provided in a portion. This contributes to high-density mounting.

The electronic apparatus 31 can be used in a first state (e.g., a horizontally long state) in which the second end 4b is up and the first end 4a is down. In addition, the electronic apparatus 31 can be used in a second state (e.g., vertically long state) in which the first side wall 38 is up and the second side wall 39 is down. The electronic apparatus 31 includes, for example, an accelerator sensor (i.e., gravity sensor) which detects whether the electronic apparatus 31 is in the first state or the second state.

The electronic apparatus 31 changes the display of images between a horizontally long image corresponding to the first state and a vertically long image corresponding to the second state on the basis of the detection result. The change in the display of the display screen 17 is controlled by, for example, the first board 51 (i.e., control unit).

The electronic apparatus 31 cannot be used with the second side wall 39 up and the first side wall 38 down. Specifically, an inverted image is not displayed on the display screen 17 of the electronic apparatus 31 with the second side wall 39 up and the first side wall 38 down. In this way, the user can be prevented from using the electronic apparatus 31 with the second side wall 39 up and the first side wall 38 down. That is, when the electronic apparatus 31 is used while being vertically arranged, the first side wall 38 needs to be disposed on the upper side.

As shown in FIG. 10, an opening 68a of the pen accommodating portion 68 is provided in the first side wall 38. In this way, when the electronic apparatus 31 is used while being vertically arranged, the opening 68a of the pen accommodating portion 68 needs to be disposed on the upper side. In this way, a pen accommodated in the pen accommodating portion 68 can be suppressed from falling.

The exhaust holes 42 are provided in the first side wall 38. In this way, when the electronic apparatus 31 is used while being vertically arranged, the exhaust holes 42 needs to be disposed on the upper side (that is, the side opposite to the user). In this way, air can be suppressed from being discharged from the exhaust holes 42 to the user.

The above-mentioned structure has the following functions.

In general, it is assumed that the user holds the slate PC with the hands and uses it. When using the slate PC horizontally placed on the desk, the user becomes posture looking into the display screen from above. Therefore, it cannot be said that user convenience is good. In particular, in the case of a large-screen slate PC, it cannot be said that the visibility of the display screen is good.

On the other hand, the housing 4 of the electronic apparatus 31 according to this embodiment includes the first end 4a, the second end 4b which is opposite to the first end 4a, and the upper wall 11 between the first end 4a and the second end 4b. The second end 4b is thicker than the first end 4a. The upper wall 11 comprises the opening through which the display screen 17 is exposed. In this way, when the electronic apparatus 31 is placed on the mounting surface S, the display screen 17 is inclined downward. That is, the electronic apparatus 31 is tilted toward the user. Therefore, the visibility of the display screen 17 by the user is improved and the user convenience of the electronic apparatus 31 is improved.

In this embodiment, the housing 4 includes the first bottom wall 12 which extends substantially parallel to the display screen 17 at the first distance t1 from the display screen 17 and the second bottom wall 13 which extends substantially parallel to the display screen 17 at the second distance t2, which is greater than the first distance t1, from the display screen 17. In this way, the electronic apparatus 31 in which the second end 4b is thicker than the first end 4a and which appears to be thin can be provided.

In this embodiment, the housing 4 includes the slope 14 disposed between the first bottom wall 12 and the second bottom wall 13. In this way, there is no angulated portion between the first bottom wall 12 and the second bottom wall 13 and the thickness of the electronic apparatus 31 can be reduced.

In this embodiment, at least a portion of the first board 51, the second board 52, the heat-generating component 56, the heat sink 54, and the fan 53 are disposed between the display 5 and the second bottom wall 13. That is, thick (i.e., high) components are separated from the first bottom wall 12 and are mounted between the display 5 and the second bottom wall 13. In this way, the distance between the first bottom wall 12 and the upper wall 11 can be reduced. As a result, the electronic apparatus 31 can seem to be thin.

In this embodiment, the second leg 34 is higher than the first leg 33. Therefore, even when the second end 4b is not significantly thicker than the first end 4a, the display screen 17 is allowed to be inclined at an arbitrary tilt angle.

(Mounting Structure of Antenna and Speaker)

Next, the mounting structure of the antenna and the speaker will be described. As shown in FIG. 11, antennas 71a and 71b and speakers 72a and 72b are provided in the first region A1 of the housing 4. That is, the antennas 71a and 71b and the speakers 72a and 72b are disposed between the display 5 and the first bottom wall 12. Each of the antennas 71a and 71b and the speakers 72a and 72b is an example of a component which generates less heat than the heat-generating component 56.

As shown in FIG. 11, the antennas 71a and 71b are separately provided at the left and right ends of the housing 4. That is, the first antenna 71a is adjacent to the first side wall 38. The second antenna 71b is adjacent to the second side wall 39. In other words, the first antenna 71a is disposed at the front right corner of the housing 4. The second antenna 71b is disposed at the front left corner of the housing 4.

In addition, a plurality of conductive members 73 are provided in the housing 4. The plurality of conductive members 73 are arranged so as to surround the first antenna 71a and the second antenna 71b. That is, the plurality of conductive members 73 are disposed between the first antenna 71a and the fan 53, between the first antenna 71a and the first board 51, and between the first antenna 71a and the second board 52. In addition, a plurality of other conductive members 73 are disposed between the second antenna 71b and the fan 53, between the second antenna 71b and the first board 51, and between the second antenna 71b and the second board 52.

In other words, the first antenna 71a is surrounded by the first side wall 38, the front wall 36, and the conductive members 73. That is, the first antenna 71a is disposed between the first side wall 38 and the conductive members 73. The first antenna 71a is disposed between the front wall 36 and the conductive members 73. The second antenna 71b is surrounded by the second side wall 39, the front wall 36, and the conductive members 73. That is, the second antenna 71b is disposed between the second side wall 39 and the conductive members 73. The second antenna 71b is disposed between the front wall 36 and the conductive members 73.

An example of the conductive member 73 is a so-called gasket and includes a sponge member and a conductive film attached to the surface of the sponge member. The conductive member 73 is interposed between the metal base 47 and the metal middle plate 49 and is electrically connected to at least one of the base 47 and the middle plate 49. The conductive member 73 functions as an electro-static discharge (ESD) member or an electro-magnetic interference (EMI) member.

As shown in FIG. 11, a pair of speakers 72a and 72b are separately provided at the left and right ends of the front wall 36. As shown in FIG. 5, the front wall 36 includes sound holes 74 (i.e., openings) which are formed in the first direction D1. The speakers 72a and 72b face the sound holes 74 and emit sounds in the first direction D1. That is, the electronic apparatus 31 emits sounds from the front wall 36.

(Battery Mounting Structure)

Next, a battery mounting structure will be described. As shown in FIG. 9, the electronic apparatus 31 includes a battery 75. As shown in FIG. 8, the second end 4b of the housing 4 includes a battery accommodating portion 76 (i.e., a battery attachment portion or a battery receiver) to which the battery 75 is attached. The battery accommodating portion 76 includes a pair of protrusions 76a and 76b which protrude from the left and right ends of the housing 4 to the rear side and a recess 76c which is provided between the protrusions 76a and 76b. The recess 76c is recessed from the protrusions 76a and 76b by a depth corresponding to the battery 75. The recess 76c is opened in the backward direction and the vertical direction. The recess 76c extends between the second bottom wall 13 and the upper wall 11. That is, the recess 76c extends between the base 47 and the mask 48.

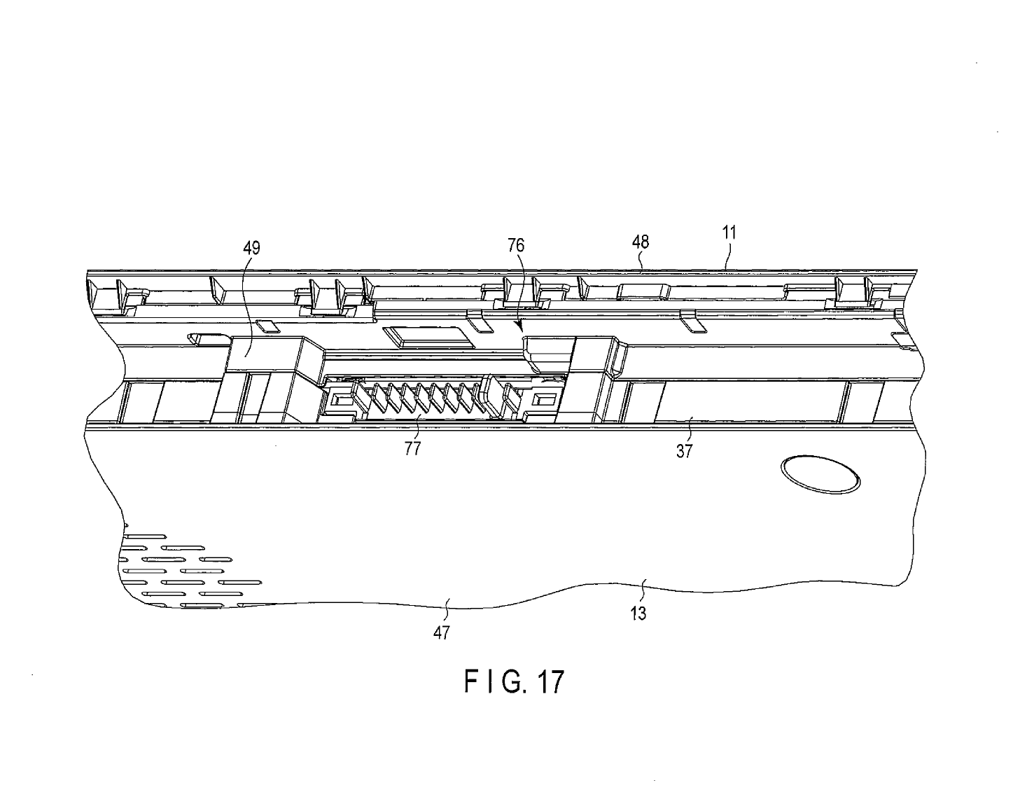

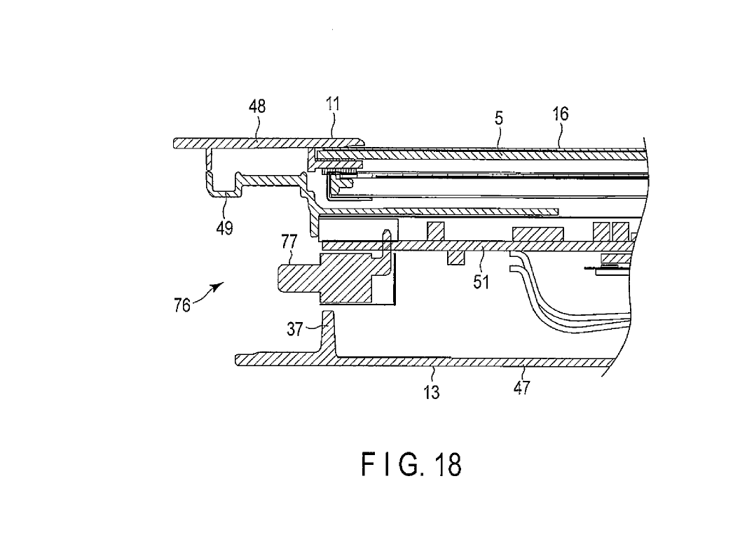

As shown in FIGS. 17 and 18, a connector 77 is provided in the recess 76c. The connector 77 is a battery connector to which the battery 75 is connected. In other words, the first connector 18 is provided at the first end 4a (e.g., front end) of the housing 4 and the connector 77 is provided at the second end 4b (e.g., rear end) of the housing 4. That is, the battery connectors are provided at two opposite ends of the housing 4.

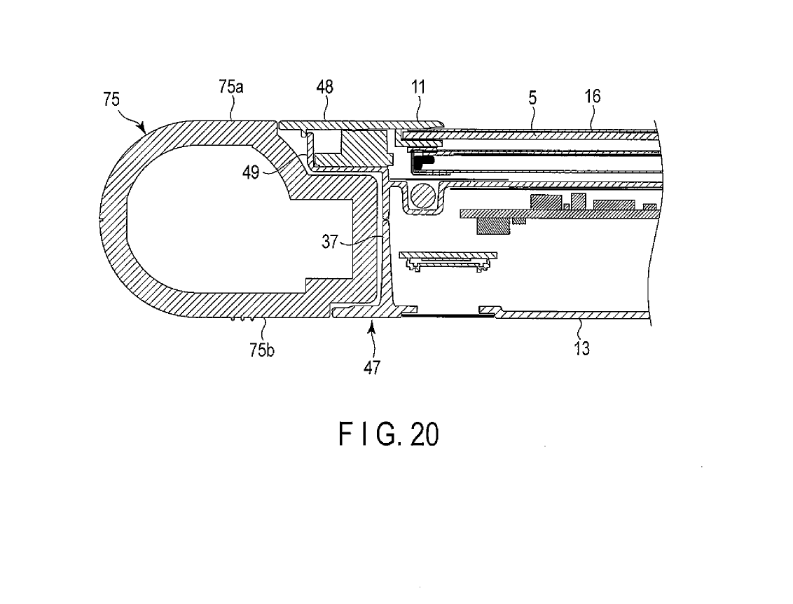

As shown in FIGS. 5 and 20, the battery 75 is removably attached to the second end 4b of the housing 4 and is arranged along the second end 4b of the housing 4. The battery 75 is accommodated in the recess 76c of the battery accommodating portion 76. The battery 75 has a thickness that is substantially equal to that of the second end 4b of the housing 4.

In this way, as shown in FIG. 20, the upper surface 75a of the battery 75 is substantially flush with the upper wall 11 of the housing 4. The lower surface 75b of the battery 75 is substantially flush with the second bottom wall 13 of the housing 4. The battery 75 is aligned with at least a portion of the display 5 in the first direction D1. For example, the battery 75 is horizontally aligned with at least a backlight of the display 5. According to this structure, the thickness of the electronic apparatus 31 can be reduced. In this embodiment, the display 5 is arranged within the thickness of the battery 75.

(Assembly Structure of Housing)

Next, the assembly structure of the housing 4 will be described.

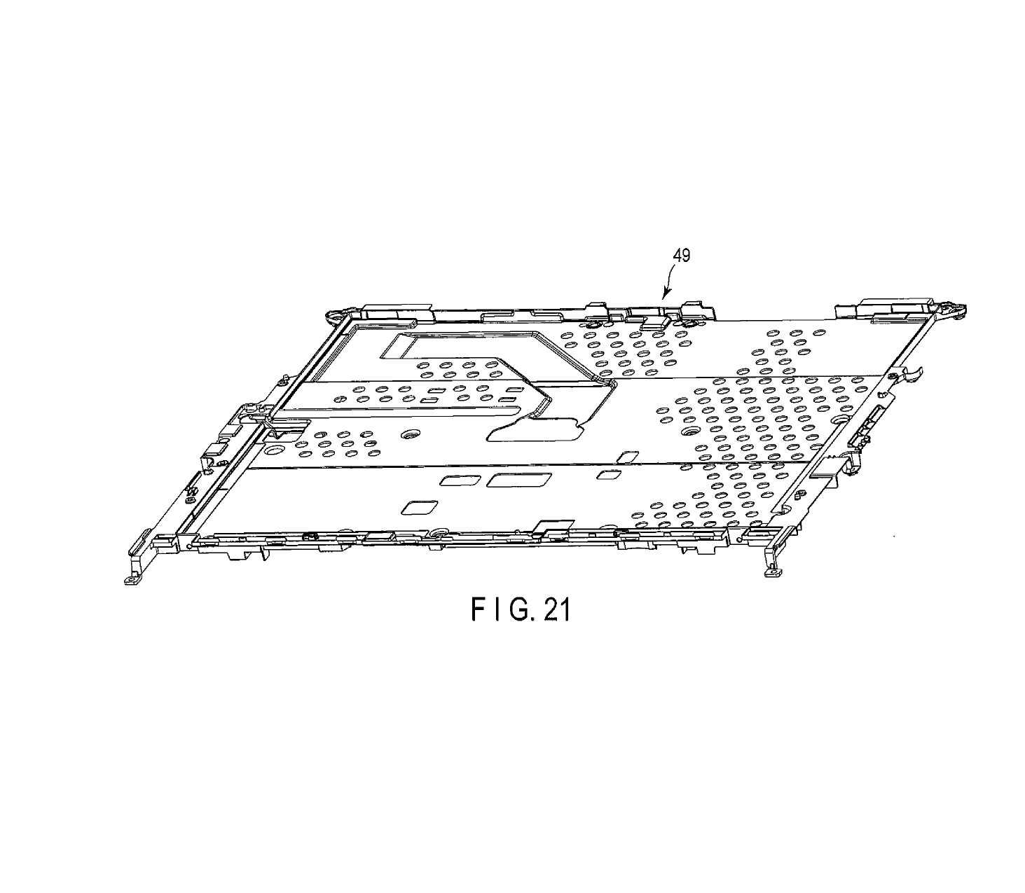

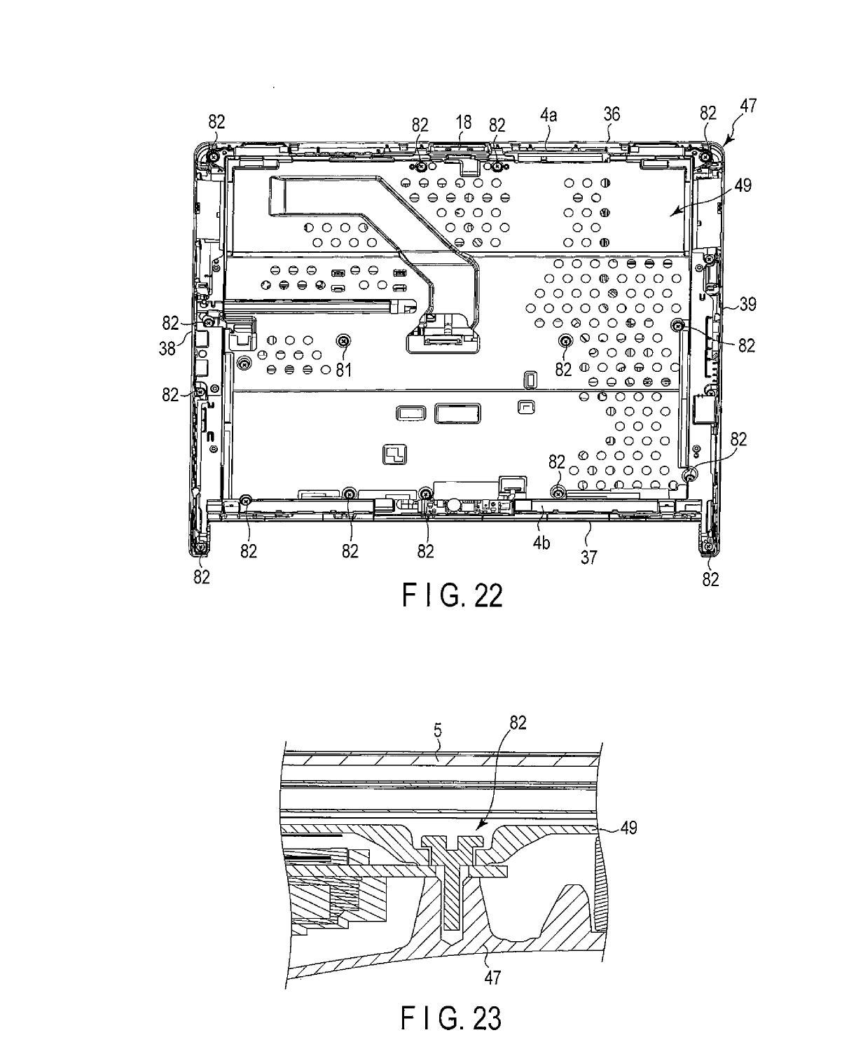

FIGS. 21 and 22 show the middle plate 49. As shown in FIG. 22, the middle plate 49 is fixed to the base 47 by a plurality of screws 81 and 82. Specifically, the plurality of screws 81 and 82 include, for example, a first screw 81 and a plurality of second screws 82. The first screw 81 is a general screw. The second screw 82 is a shoulder screw (see FIG. 23). As shown in FIG. 22, the first screw 81 is inserted into a substantially central portion of the middle plate 49. The plurality of second screws 82 are inserted into all of the ends of the middle plate 49.

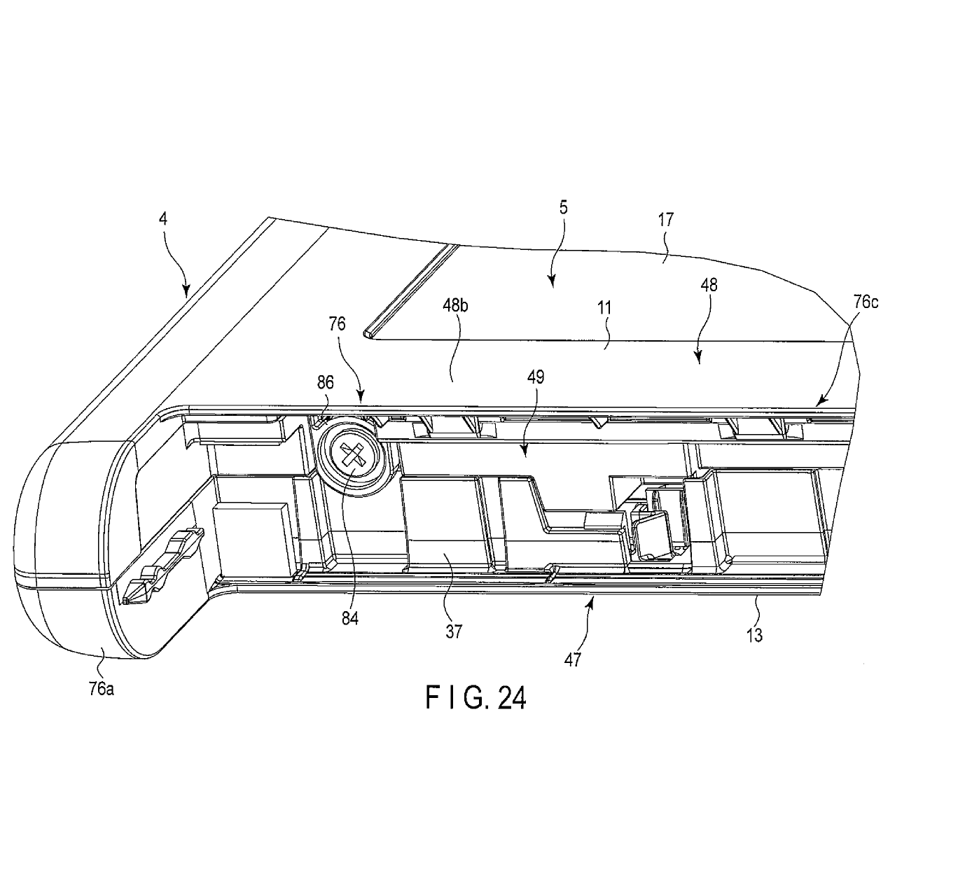

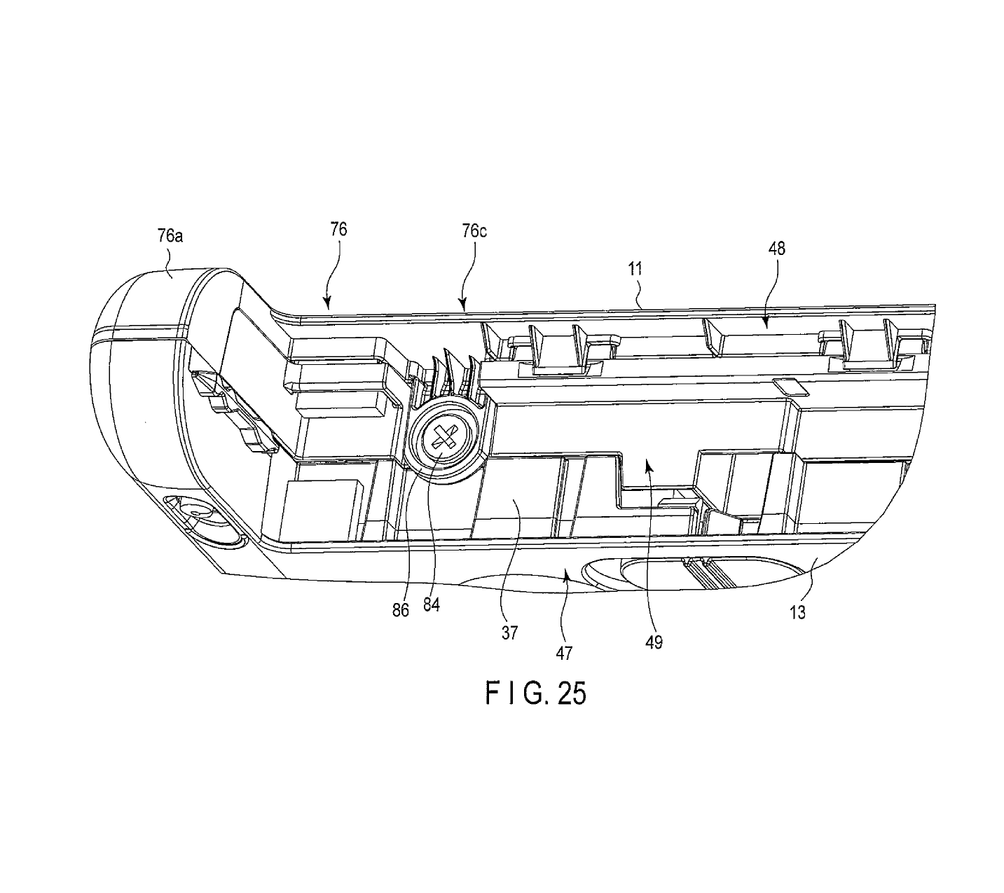

As shown in FIGS. 24 and 25, the middle plate 49 is disposed between the base 47 and the mask 48. The base 47 and the mask 48 do not have portions covering the rear end of the middle plate 49. In this way, the rear end of the middle plate 49 is exposed to the recess 76c of the battery accommodating portion 76. That is, the rear end of the middle plate 49 is exposed to the outside of the housing 4. In other words, the middle plate 49 forms a portion of the outer wall of the housing 4.

According to this structure, a bent portion covering the middle plate 49 is not provided at the rear end of the mask 48. Therefore, the shape of the mask 48 can be simplified. The middle plate 49 exposed to the recess 76c is covered and hidden by the battery 75. Therefore, the outward appearance of the electronic apparatus can be improved.

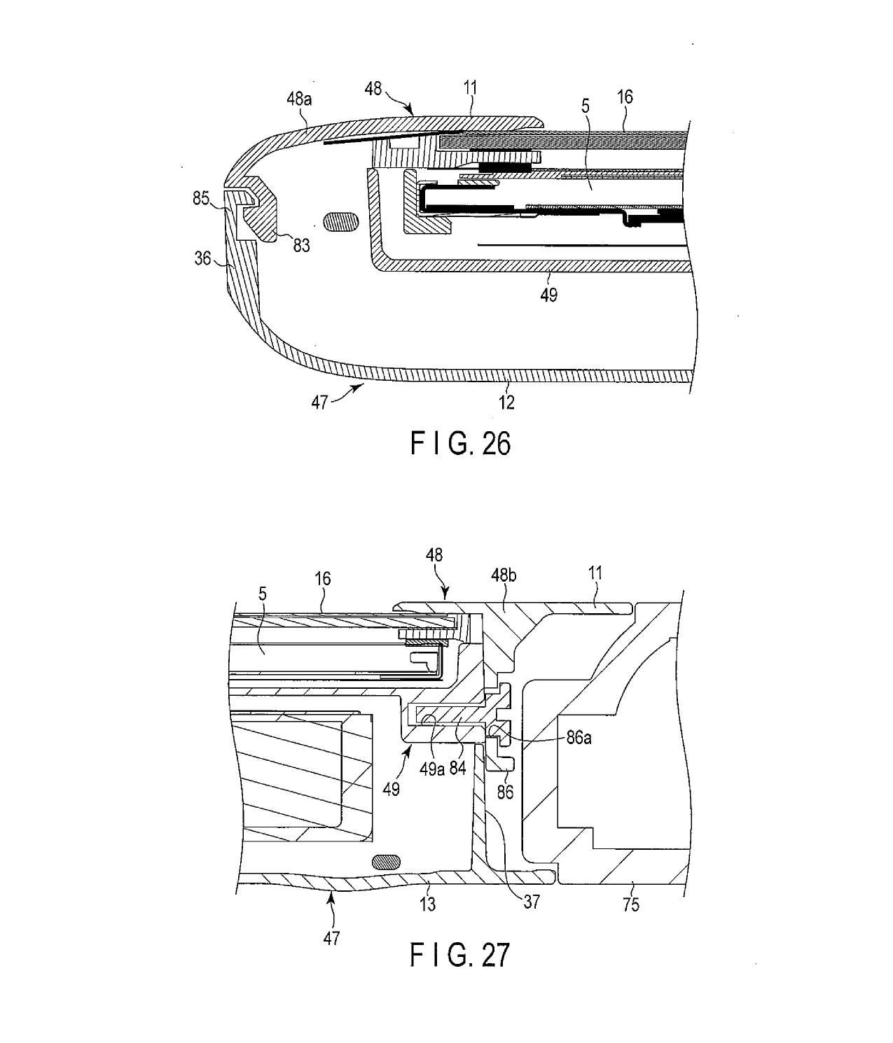

As shown in FIGS. 25 to 27, the mask 48 is fixed to the base 47 and the middle plate 49 by a hook 83 and two screws 84. As shown in FIG. 26, the front end 48a (i.e., first end) of the mask 48 includes the hook 83 (i.e., first engaging portion). The base 47 includes a hook receiver 85 (i.e., second engaging portion) which can be engaged with the hook 83. The hook receiver 85 is provided in the inner surface of the housing 4. The hook 83 is engaged with the hook receiver 85 from the inside of the housing 4. In this way, the front end 48a of the mask 48 is fixed to the base 47.

As shown in FIG. 9, the rear end 48b (i.e., second end) of the mask 48 includes a plurality of fixing portions 86 which protrude from the upper wall 11 and face the middle plate 49 from the rear side. For example, two fixing portions 86 are provided. The fixing portion 86 includes a through hole 86a into which the screw 84 is inserted. As shown in FIG. 27, the middle plate 49 includes screw holes 49a facing the through holes 86a. The screws 84 are inserted into the screw holes 49a through the through holes 86a to fix the rear end 48b of the mask 48 to the middle plate 49.

In this way, the front end 48a of the mask 48 is fixed to the base 47 by the hooks 83 and the rear end 48b of the mask 48 is fixed to the middle plate 49 by the screws 84. Therefore, the mask 48 is fixed to the base 47 and the middle plate 49.

According to this structure, the mask 48 can be fixed with a relatively small number of screws 84 (for example, two screws 84). In this way, the number of components and costs can be reduced and thus assembly workability can be improved. In addition, the screws 84 for fixing the mask 48 are exposed only through the battery accommodating portion 76. The screws 84 are covered and hidden by the battery 75. Therefore, the outward appearance of the electronic apparatus can be improved.

(Arrangement Structure of Buttons)

As shown in FIG. 5, the first side wall 38 includes a first button 87. As shown in FIG. 8, the second side wall 39 includes a second button 88. The first button 87 and the second button 88 are provided in the protrusions 76a and 76b of the battery accommodating portion 76. That is, the first button 87 and the second button 88 are separately disposed on either side of the battery 75. The first button 87 and the second button 88 face the side of the housing 4.

The first button 87 is a power button for turning on/off the electronic apparatus 31. The second button 88 is a secure attention sequence (SUS) button. That is, the second button 88 has a function corresponding to the simultaneous pressing of a “Ctrl” key, an “Alt” key, and a “Del” key provided in a keyboard of the general PC system and also has an application maintenance function. For example, when an application does not respond, the user can press the second button 88 to forcibly end the application which does not respond.

The electronic apparatus 31 according to this embodiment does not include a keyboard as a hardware component. In the electronic apparatus 31, when an application does not respond, a software keyboard is not likely to operate. Therefore, a SUS switch is provided to ensure convenience. The SUS switch is allocated to the second button 88 which is disposed on the left side as viewed from the user. That is, the second button 88 is disposed at a position where it is difficult for the right-handed user to press the second button 88. In this way, a false operation of the second button 88 due to a button pressing error can be suppressed.

(Rib Structure for Suppressed False Operation)

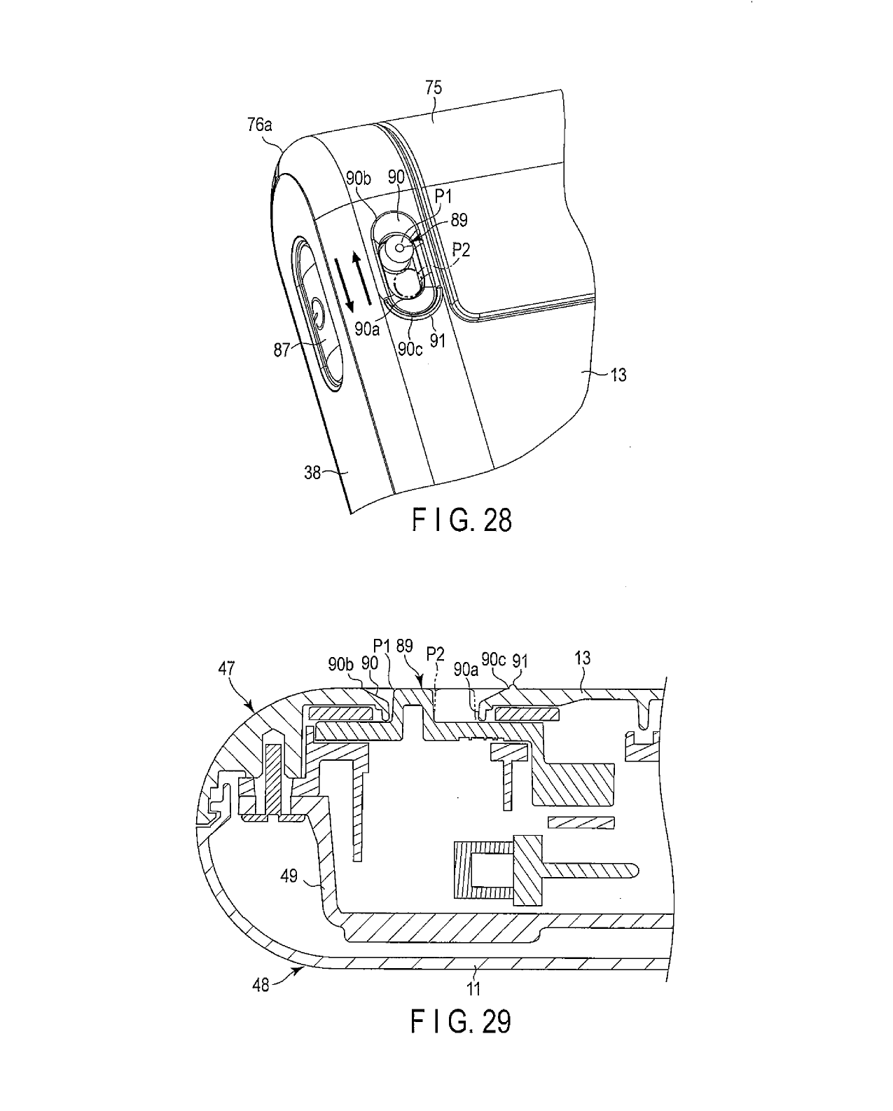

Next, a rib structure for suppressing a false operation will be described. As shown in FIG. 28, a lock 89 (i.e., lock switch) for the first button 87 (e.g., power button) is provided on the lower surface of the housing adjacent to the first button 87. The lock 89 is movable between a first position P1 (i.e., unlock position) and a second position P2 (e.g., lock position).

When the lock 89 is at the first position P1, the first button 87 can be operated and receive an input. When the lock 89 is at the second position P2, the operation of the first button 87 is restricted and the first button 87 does not receive an input. In this way, the user moves the lock 89 to the second position P2 to prevent the false operation of the first button 87.

As shown in FIGS. 28 and 29, for example, a mortar-shaped recess 90 is provided in the lower surface (e.g., second bottom wall 13) of the housing. An opening 90a is provided in the bottom of the recess 90. The lock 89 is provided in the opening 90a and is exposed to the outside of the housing 4. The lock 89 is disposed in the recess 90 and does not protrude toward the outside of the recess 90. That is, the lock 89 does not protrude from the lower surface (e.g., second bottom wall 13) of the housing to the outside. In this embodiment, the leading end of the lock 89 is substantially flush with the lower surface (e.g., second bottom wall 13) of the housing. In addition, the leading end of the lock 89 may be disposed closer to the bottom of the recess 90 than the lower surface (e.g., second bottom wall 13) of the housing.

As shown in FIG. 28, the recess 90 is a long hole and includes a first edge 90b (i.e., first end) and a second edge 90c (i.e., second end). The first edge 90b faces the lock 89 at the first position P1. The second edge 90c is opposite to the first edge 90b and faces the lock 89 at the second position P2.

As shown in FIGS. 28 and 29, a rib 91 for suppressing a false operation is provided at the second edge 90c of the recess 90. The rib 91 is an example of a “protruding portion” or a “protrusion”. The rib 91 protrudes from the lower surface (e.g., second bottom wall 13) of the housing to the outside of the housing 4 and has an arc shape along the second edge 90c. The rib 91 protrudes outer side of the housing 4 than the leading end of the lock 89. The rib 91 faces the lock 89 at the second position P2 opposite to the first position P1.

For example, in an electronic apparatus without including the rib 91, when the electronic apparatus is put into a bag with the lock 89 moved to the second position P2, the lock 89 is likely to be caught by the inner surface of the bag and be unlocked. Therefore, in this embodiment, the rib 91 is provided at the second edge 90c. The provision of the rib 91 can suppress the lock 89 from being erroneously unlocked.

(Attachment Structure of Connector Cover)

Next, the attachment structure of a connector cover will be described with reference to FIGS. 8, 30, and 31. As shown in FIG. 8, a connector 92 is provided in the second side wall 39. An opening 93 through which the connector 92 is exposed to the outside is provided in the second side wall 39. A cover (i.e., connector cover) for covering the connector 92 is removably attached to the opening 93. That is, when the cover 94 is removed from the opening 93, the connector 92 is exposed to the outside. The connector 92 is fixed to the middle plate 49.

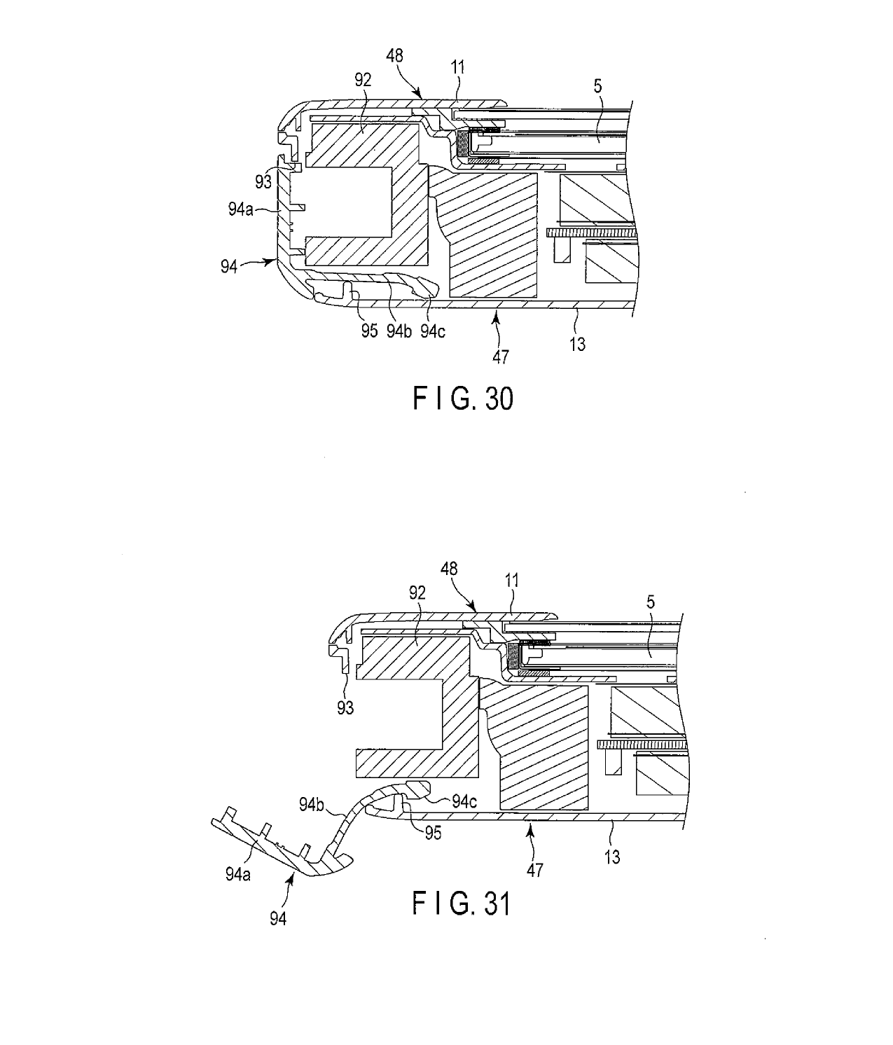

As shown in FIG. 30, a protrusion 95 protruding toward the connector 92 is provided on the inner surface of the base 47 (i.e., housing 4). The cover 94 includes a cover portion 94a (i.e., cover body) which covers the connector 92 from the outside, a supporting portion 94b which supports the cover portion 94a, and a retaining portion 94c. The supporting portion 94b extends from the end of the cover portion 94a to the inside of the protrusion 95 in the housing 4 through the connector 92 and the protrusion 95.

The retaining portion 94c is provided at the leading end of the supporting portion 94b and is disposed on the inside of the protrusion 95 in the housing 4. The thickness of the retaining portion 94c is greater than the gap between the connector 92 and the protrusion 95. Therefore, the retaining portion 94c cannot be moved to the outside of the housing 4 over the protrusion 95. In this way, the cover 94 is not taken off from the housing 4.

According to this structure, the cover 94 of the connector 92 can be held by the connector 92. Therefore, a fixing member for fixing the cover 94 can be omitted. As a result, manufacturing costs can be reduced.

(Power Socket Structure)

As illustrated in FIG. 8, the housing 4 includes a power connector 96. For example, a jack (i.e., plug) connected to a household power supply can be connected to the power connector 96. An opening 97 is provided in the second side wall 39. The power connector 96 is exposed to the outside of the housing 4 through the opening 97. The base 47 including the second side wall 39 is made of a metal material.

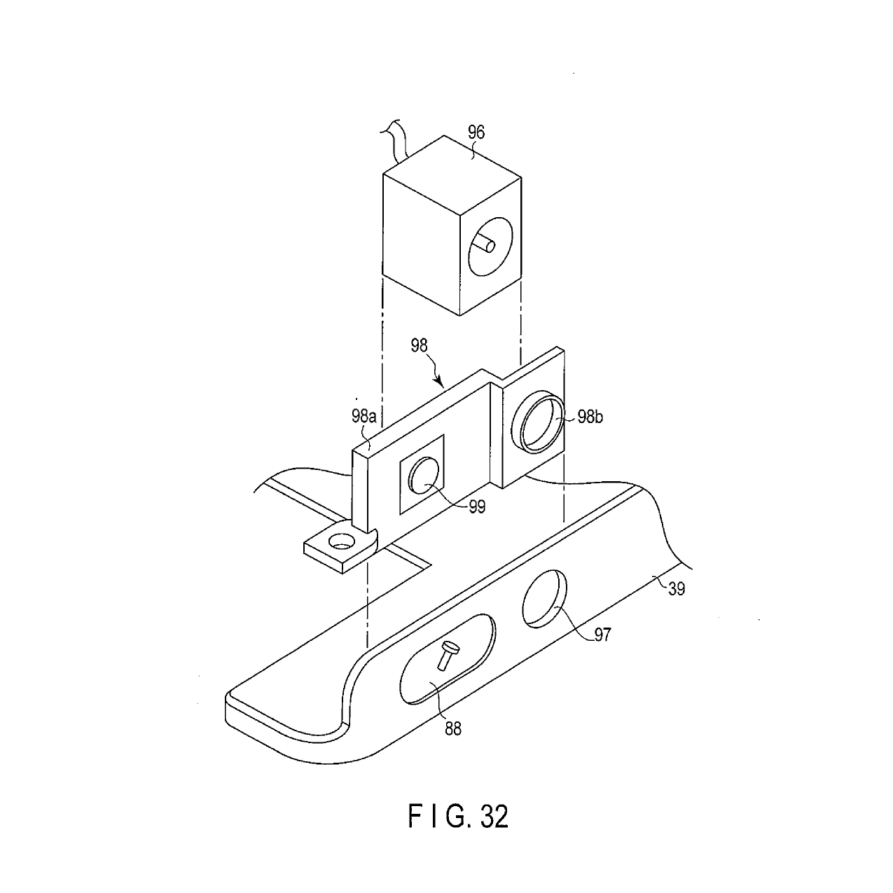

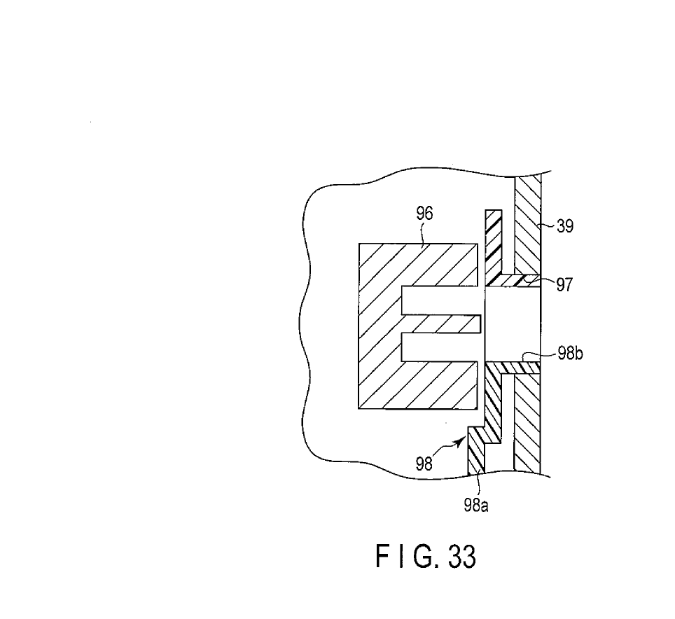

As illustrated in FIGS. 32 and 33, a non-conductive member 98 (i.e., non-metal member) is provided on the rear side of the second side wall 39. The non-conductive member 98 is made of, for example, a resin. The non-conductive member 98 includes a first portion 98a and a second portion 98b.

The first portion 98a is disposed on the rear side of the second button 88 and faces the second button 88. The first portion 98a is a holder holding a switch 99. The switch 99 faces the second button 88 and is operated by the second button 88.

The second portion 98b is disposed between the power connector 96 and the opening 97 of the second side wall 39. The second portion 98b has a cylindrical portion which is along the inner circumferential surface of the opening 97 and is inserted into the opening 97. The second portion 98b is a protective member (a so-called DC-in socket) that prevents the direct contact between the second side wall 39 and the power connector 96.

In other words, in this embodiment, the protective member inserted into the opening 97 is formed integrally with the holder holding the switch 99. In this way, the number of components and the manufacturing costs of the electronic apparatus 31 can be reduced. The connector protected by the non-conductive member 98 is not limited to the power connector, but the non-conductive member 98 may protect other connectors.

(Housing Structure of Dock)

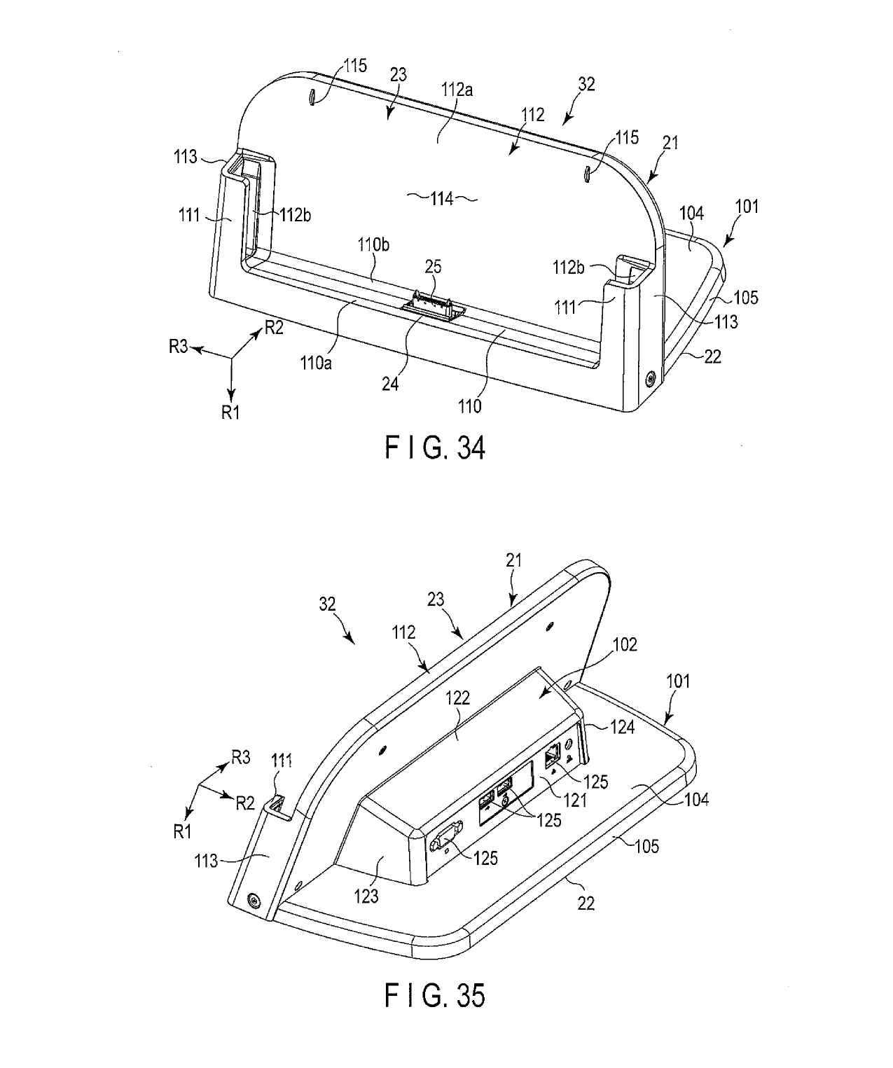

Next, the dock 32 (i.e., docking portion or docking station) to which the electronic apparatus 31 is removably attached will be described with reference to FIGS. 34 to 50. The dock 32 is an example of an “electronic apparatus” and is also an example of a “supporting unit”, a “supporting portion”, a “stand”, a “connector”, or an “expansion unit”.

As shown in FIGS. 34 and 35, the dock 32 includes the second housing 21. The second housing 21 includes a base 101, a holder 23, and an accommodating portion 102. The base 101 (i.e., base portion) has a flat box shape and is placed on the mounting surface S. The base 101 includes a bottom wall 22, an upper wall 104, and a circumferential wall 105. The bottom wall 22 has a plate shape (i.e., planar shape) and is substantially parallel to the mounting surface S. The bottom wall 22 is placed on the mounting surface S and faces the mounting surface S. The upper wall 104 extends substantially in parallel to the bottom wall 22. The circumferential wall 105 rises from the end of the bottom wall 22 and connects the bottom wall 22 and the upper wall 104.

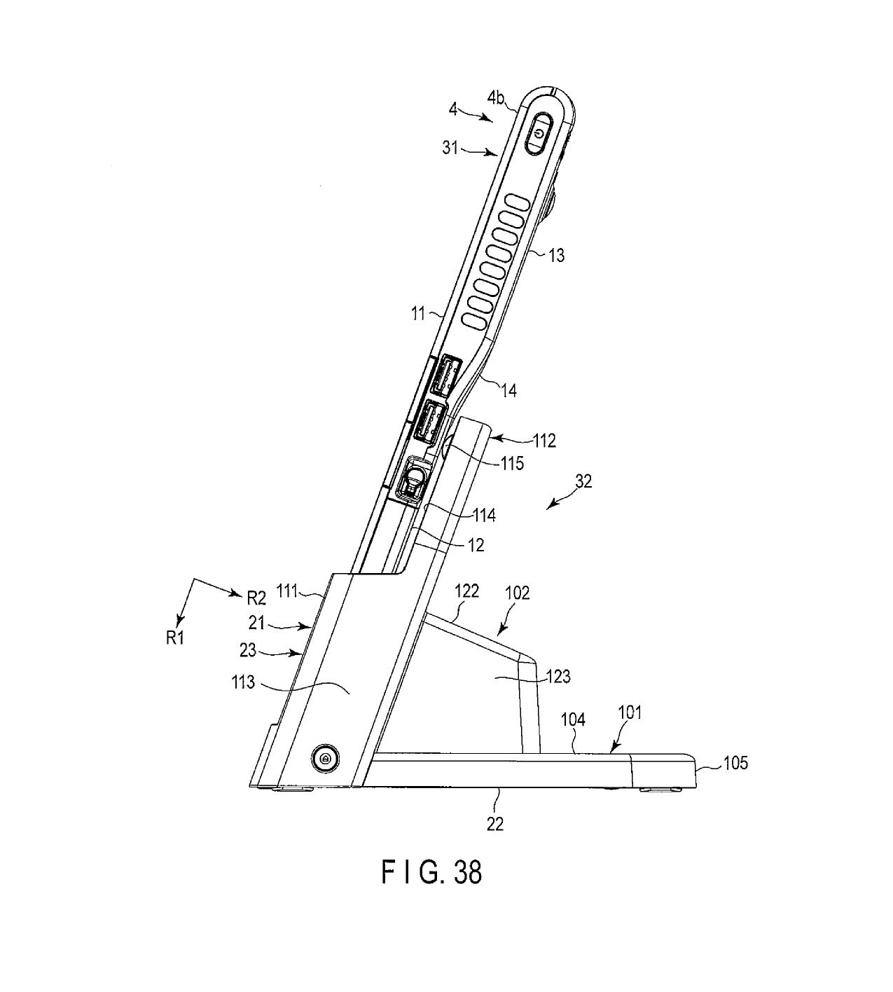

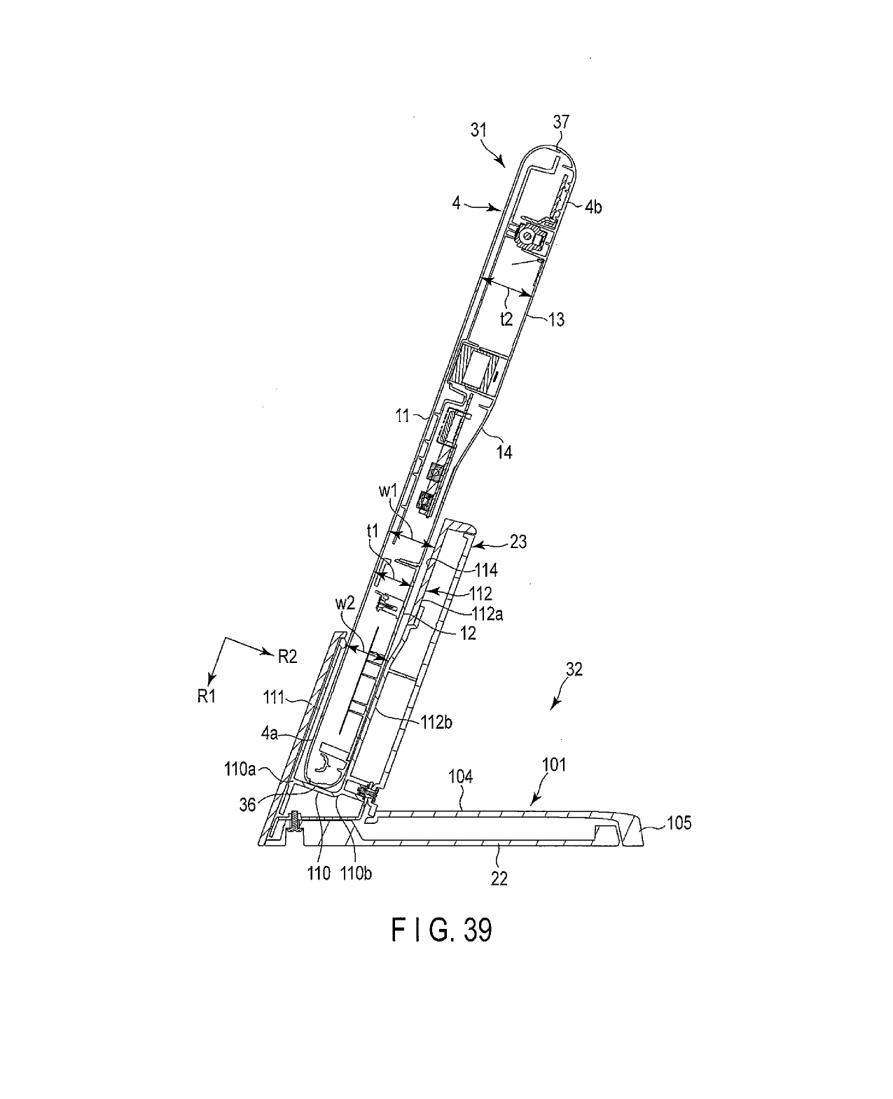

As shown in FIGS. 34 and 35, the holder 23 is provided at the front end of the base 101 and rises upward with respect to the base 101. The holder 23 is an example of a “holding portion”. As shown in FIGS. 37 to 40, the electronic apparatus 31 is removably attached to the holder 23. The holder 23 configured to hold the electronic apparatus 31 so that the electronic apparatus 31 stands with respect to the mounting surface S. As shown in FIGS. 38 and 39, the holder 23 is inclined to the rear side relative to the bottom wall 22. Therefore, the display screen 17 is inclined to the rear side with the electronic apparatus 31 supported by the dock 32. In this way, visibility and usability are improved.

As another point of view, a first direction R1, a second direction R2, and a third direction R3 are newly defined. As shown in FIG. 38, the first direction R1 is substantially parallel to the holder 23 which is inclined with respect to the bottom wall 22. That is, the first direction R1 is inclined with respect to the bottom wall 22. The first direction R1 is substantially parallel to the display screen 17, the upper wall 11, the first bottom wall 12, and the second bottom wall 13 when the electronic apparatus 31 is inserted into the holder 23.

The second direction R2 is a direction crossing (for example, a direction substantially perpendicular to) the first direction R1. The second direction R2 is, for example, the thickness direction of the holder 23. As shown in FIG. 34, the third direction R3 is a direction crossing (for example, a direction substantially perpendicular to) the first direction R1 and the second direction R2. The third direction R3 is, for example, the longitudinal direction (e.g., width direction) of the holder 23.

As shown in FIGS. 38 and 39, the electronic apparatus 31 is inserted into the holder 23 in the first direction R1. Specifically, the electronic apparatus 31 is attached to the holder 23, with the display screen 17 aligned with the first direction R1 (that is, with the display screen 17 substantially parallel to the first direction R1). That is, the electronic apparatus 31 is inserted into the holder 23 in a direction substantially parallel to the display screen 17.

As shown in FIG. 34, the holder 23 includes a receiving wall 110, first supporting walls 111, a second supporting wall 112, and third supporting walls 113. The receiving wall 110 (e.g., bottom wall) is provided at a lower part of the holder 23 and extends substantially in the horizontal direction. The receiving wall 110 faces the front wall 36 of the electronic apparatus 31. The receiving wall 110 is inclined with respect to the bottom wall 22 and is substantially perpendicular to the first direction R1. The receiving wall 110 comes into contact with the front wall 36 of the electronic apparatus 31 in the first direction R1 and receives the front wall 36 of the electronic apparatus 31. The receiving wall 110 includes a first end 110a (e.g., front end) and a second end 110b (e.g., rear end) opposite to the first end 110a.

The first supporting walls 111 (i.e., first supporting portions) are partially provided at the left and right ends (i.e., either end in the longitudinal direction) of the holder 23. The first supporting wall 111 rises from the first end 110a of the receiving wall 110 and is substantially parallel to the first direction R1. The first supporting wall 111 is substantially parallel to the upper wall 11 of the electronic apparatus 31 and faces the upper wall 11 of the electronic apparatus 31. The first supporting wall 111 is an example of a “first wall” and supports the upper wall 11 of the electronic apparatus 31. The front side of the holder 23 is opened in a region in which the first supporting wall 111 is not provided.

The second supporting wall 112 (i.e., second supporting portion) is provided substantially over the entire length of the second end 110b of the receiving wall 110. The second supporting wall 112 rises from the second end 110b of the receiving wall 110 and is substantially parallel to the first direction R1. The second supporting wall 112 is substantially parallel to the first bottom wall 12 of the electronic apparatus 31 and faces the first bottom wall 12 of the electronic apparatus 31. The second supporting wall 112 is an example of a “second wall” and supports the first bottom wall 12 of the electronic apparatus 31.

As shown in FIG. 39, the second supporting wall 112 extends to be higher than the first supporting wall 111. The second supporting wall 112 faces, for example, the first bottom wall 12 of the electronic apparatus 31. The second supporting wall 112 does not cover the slope 14 and the second bottom wall 13 of the electronic apparatus 31. Therefore, with the electronic apparatus 31 supported by the holder 23, the first to third air inlets 61, 62, and 63 of the electronic apparatus 31 are exposed (i.e., opened) to the outside without being covered with the holder 23. Therefore, the electronic apparatus 31 can draw air through the air inlets 61, 62, and 63 while being inserted into the holder 23.

As shown in FIG. 34, the second supporting wall 112 includes first portions 112a and a second portion 112b. The first portions 112a form most of the second supporting wall 112. As shown in FIG. 39, a gap w1 (i.e., distance) between the first portion 112a and the first supporting wall 111 is more than the thickness (i.e., a distance t1 between the first bottom wall 12 and the upper wall 11) of the electronic apparatus 31.

As shown in FIGS. 34 and 38, the first portion 112a includes a plane 114 (i.e., planar portion) which faces the first bottom wall 12 of the electronic apparatus 31 and a projection 115 which protrudes from the plane 114 and comes into contact with the first bottom wall 12 of the electronic apparatus 31. The projection 115 is an example of a positioning portion for regulating the position of the electronic apparatus 31. The electronic apparatus 31 is supported by the projection 115 and is supported by the holder 23 while being separated from the plane 114. In this way, the surface contact between the electronic apparatus 31 and the holder 23 is prevented and a scratch is less likely to occur in the surface of the electronic apparatus 31.

As shown in FIG. 34, the second portions 112b are provided at the left and right ends of the second supporting wall 112 and face the first supporting wall 111. As shown in FIG. 39, a gap w2 (i.e., distance) between the second portion 112b and the first supporting wall 111 is substantially equal to the thickness (i.e., the distance t1 between the first bottom wall 12 and the upper wall 11) of the electronic apparatus 31. Therefore, the electronic apparatus 31 is held between the second portion 112b and the first supporting wall 111.

As shown in FIG. 34, the third supporting walls 113 (i.e., third supporting portion) are provided at the left and right ends of the holder 23 and extend between the first supporting wall 111 and the second supporting wall 112. A pair of third supporting walls 113 faces the first side wall 38 and the second side wall 39 of the electronic apparatus 31. According to this structure, the holder 23 includes the supporting walls on the front, rear, left, and right sides. Therefore, the insertion and removal of the electronic apparatus 31 into and from the dock 32 are improved and the position of the electronic apparatus 31 is stabilized.

As shown in FIG. 35, the accommodating portion 102 is provided on the rear side of the second supporting wall 112. The accommodating portion 102 has a box shape which protrudes upward from the base 101 and includes a rear wall 121, an upper wall 122, and left and right side walls 123 and 124. The rear wall 121 is recessed to the rear ends of the left and right side walls 123 and 124. The rear wall 121 is an example of a “connector attachment portion”. A plurality of connectors 125 are provided (i.e., exposed from) in the rear wall 121. In this embodiment, the connector attachment portion is located on inner side (e.g., front side) than the rear ends of the left and right side walls 123 and 124.

(Floating Structure of Connector)

Next, the floating structure of the connector will be described. As shown in FIG. 34, the receiving wall 110 of the holder 23 includes an opening 24. The dock 32 includes a second connector 25 configured to connect to the electronic apparatus 31. The second connector 25 is disposed in the opening 24 and protrudes toward the outside of the opening 24.

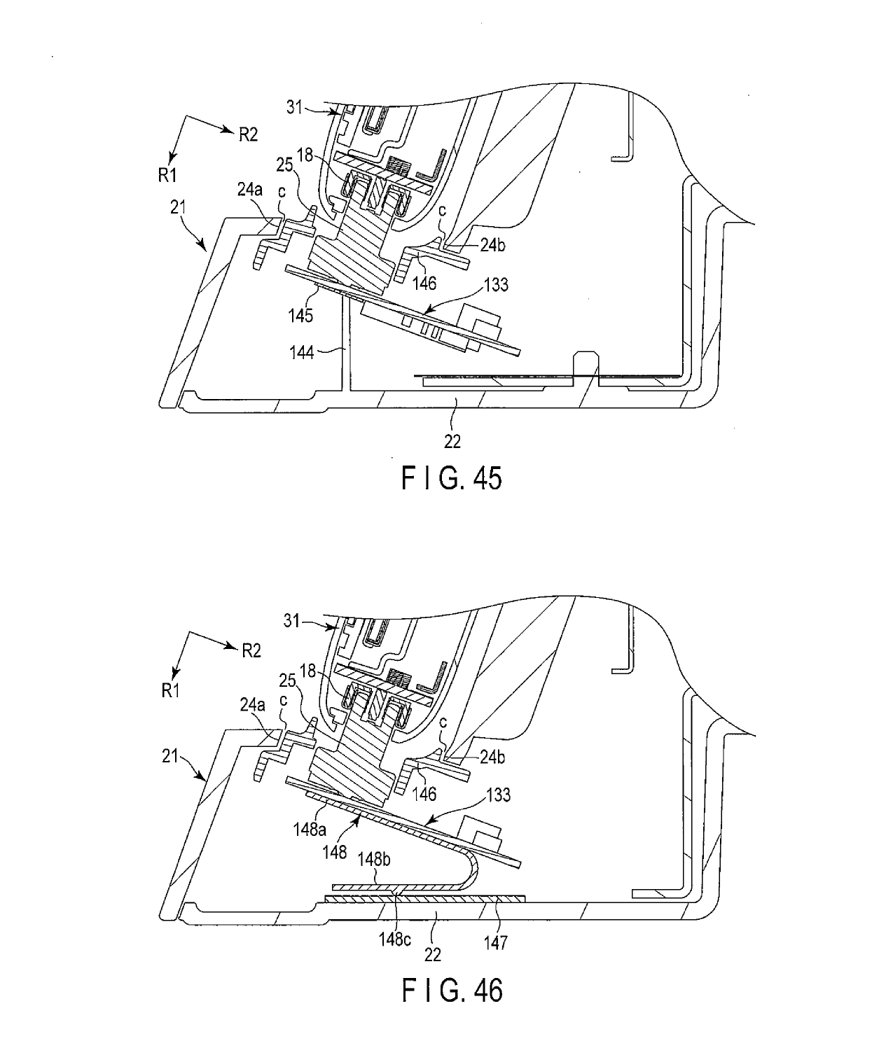

As shown in FIG. 45, the second connector 25 is inclined with respect to the bottom wall 22 and is substantially parallel to the receiving wall 110. The second connector 25 is substantially parallel to the first direction R1. The second connector 25 faces the first connector 18 of the electronic apparatus 31 in the first direction R1 and is configured to connect to the first connector 18. That is, the connectors 18 and 25 are configured to be engaged each other in the first direction R1.

As shown in FIGS. 41 to 44, the dock 32 includes a supporting base 131 and a pair of supporting portions 132. The supporting base 131 is an example of a “connector base”, a “connector holder”, a “supporter”, or a “holding portion”. The supporting base 131 is inclined with respect to the bottom wall 22 and is substantially parallel to the receiving wall 110.

The second connector 25 and a board 133 (e.g., circuit board) having the second connector 25 mounted thereon are attached to the supporting base 131. As shown in FIG. 45, the second connector 25 and the board 133 are substantially parallel to the supporting base 131 and are inclined with respect to the bottom wall 22.

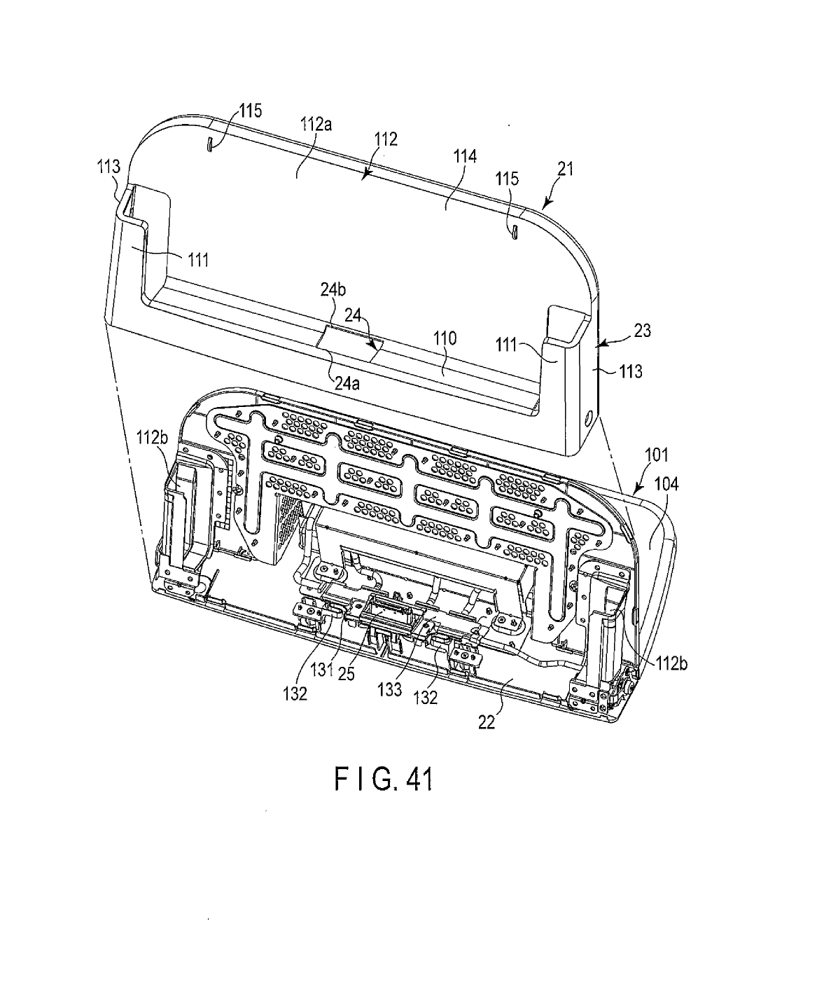

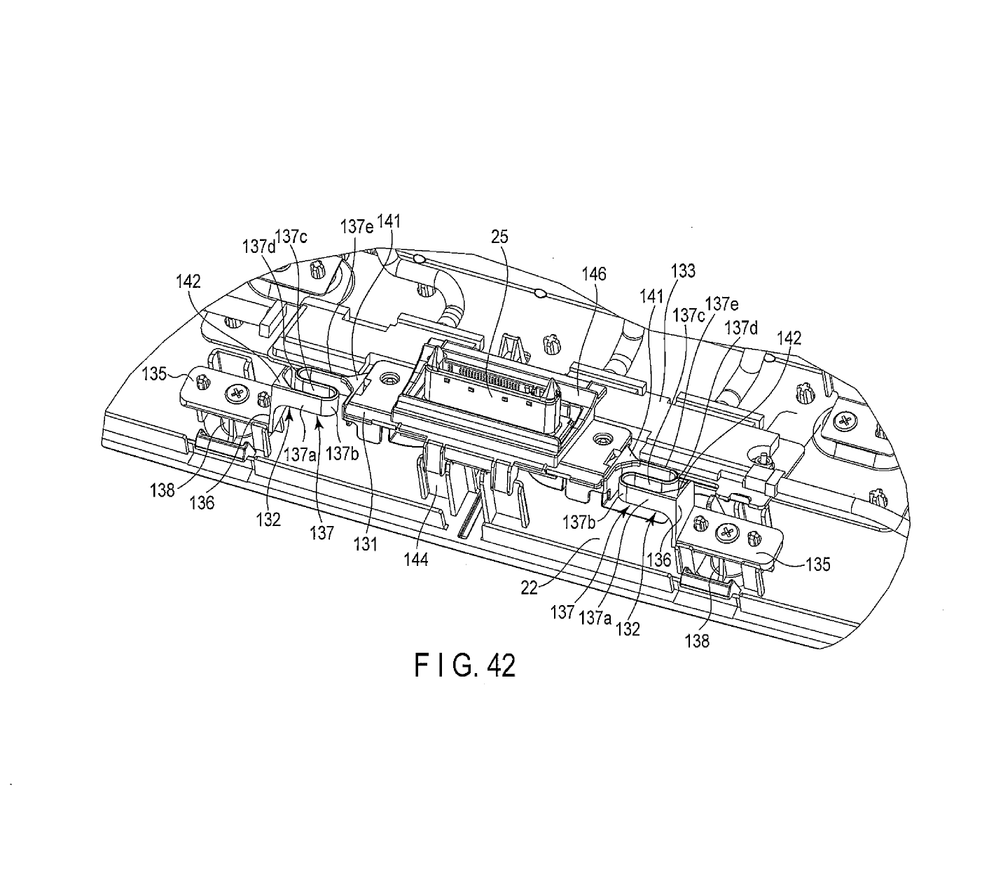

As shown in FIG. 42, a pair of supporting portions 132 are separately provided on either side of the supporting base 131 and support the supporting base 131. Each of the supporting portions 132 includes a fixing portion 135, an inclined portion 136, and an arm 137. Each of the fixing portions 135, the inclined portion 136, and the arm 137 is an example of a “portion” of the supporting portion.

The bottom wall 22 includes attachment portions 138 to which the supporting portions 132 are fixed. An example of the attachment portion 138 comprises a boss. The attachment portions 138 are provided on either side of the second connector 25. The fixing portion 135 has a plate shape along the bottom wall 22 and extends substantially in parallel to the bottom wall 22. The fixing portion 135 is attached to the attachment portion 138 of the bottom wall 22. The fixing portion 135 is fixed to the attachment portion 138 by, for example, a screw.

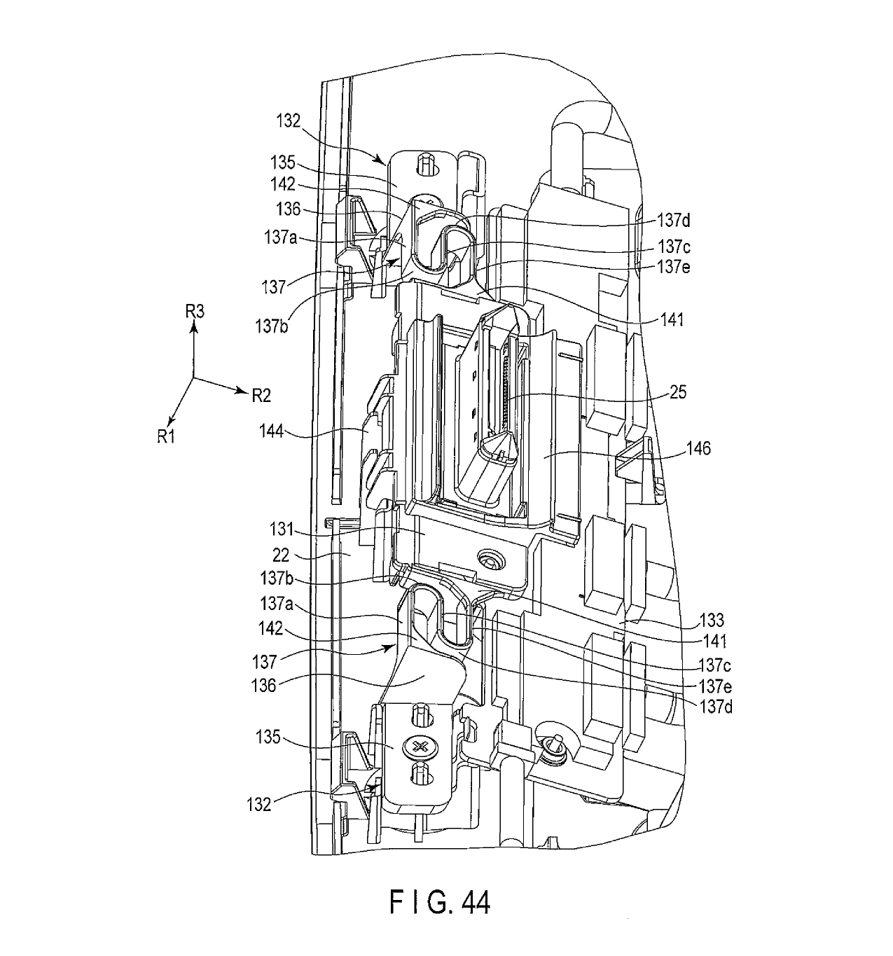

As shown in FIG. 44, the inclined portion 136 rises from the end of the fixing portion 135 and has a plate shape. The inclined portion 136 is inclined to the rear side relative to the fixing portion 135. That is, the inclined portion 136 extends from the fixing portion 135 in the first direction R1. In other words, the arm 137 is twisted with respect to the bottom wall 22 by the inclined portion 136 such that the arm 137 is inclined in the first direction R1.

The arm 137 extends between the inclined portion 136 and the supporting base 131. The arm 137 is supported by the inclined portion 136 and is inclined in the first direction R1. The arm 137 is curved in a zigzag in the second direction R2 and the third direction R3 and can be elastically deformed in the second direction R2 and the third direction R3. In this way, the arm 137 supports the second connector 25 so as to be movable in the second direction R2 and the third direction R3.

The second connector 25 is supported by the supporting portions 132 and is located at a default position (i.e., an initial position or a reference position) in a state in which the electronic apparatus 31 is not inserted into the dock 32. When the electronic apparatus 31 inserted into the dock 32 is removed from the dock 32, the second connector 25 is supported by the supporting portions 132 and returns to the default position.

As shown in FIGS. 42 to 44, the arm 137 includes three straight portions 137a, 137c, and 137e and two arc portions 137b and 137d (i.e., curved portions). The first straight portion 137a is connected to the inclined portion 136 and extends from the inclined portion 136 to the supporting base 131. The first arc portion 137b extends from the first straight portion 137a and is curved at an angle of 180 degrees in an arc shape. The second straight portion 137c extends from the first arc portion 137b to the side opposite to the supporting base 131. The second arc portion 137d extends from the second straight portion 137c and is curved at an angle of 180 degrees in an arc shape. The third straight portion 137e extends from the second arc portion 137d to the supporting base 131 and is connected to the supporting base 131.

As shown in FIG. 44, the arm 137 includes a first end 141 and a second end 142. The first end 141 is connected to the supporting base 131 and supports the supporting base 131 (i.e., second connector 25). The second end 142 is opposite to the first end 141. The second end 142 is connected to the inclined portion 136 and is supported by the inclined portion 136.

The second end 142 is in front of the first end 141. That is, the second end 142 is further away from the second supporting wall 112 than the first end 141. As shown in FIG. 44, the second end 142 is higher than the first end 141. In this way, the space between the second end 142 and the bottom wall 22 is wider than that between the first end 141 and the bottom wall 22. Therefore, the workability of the attachment of the supporting portion 132 to the attachment portion 138 is improved.

As shown in FIG. 44, at least a portion of the board 133 is disposed between the arm 137 and the second supporting wall 112. That is, the board 133 extends to the rear side of the supporting base 131. As shown in FIG. 45, the board 133 is closer to the bottom wall 22 than the supporting base 131. In this way, the height required to mount the board 133 can be reduced.

As shown in FIG. 44, the arm 137 has a plate shape along the first direction R1. Therefore, the strength of the arm 137 in the first direction R1 is greater than that of the arm 137 in the second direction R2 or the third direction R3. That is, the arm 137 can be elastically deformed in the second direction R2 and the third direction R3 and is less likely to be deformed in the first direction R1. The arm 137 can receive a relatively large load in the first direction R1.

As shown in FIG. 45, a receiver 144 receiving the supporting base 131 (i.e., board 133) is provided in the second housing 21. The receiver 144 can support the supporting base 131 (i.e., board 133) from the side opposite to the first connector 18. The receiver 144 receives force applied to the second connector 25 in the first direction R1. That is, the receiver 144 receives at least a portion of the force applied to the second connector 25 when the electronic apparatus 31 is attached to the second connector 25. In other words, the receiver 144 regulates the movement of the second connector 25 in the first direction R1.

In this way, the position of the second connector 25 in the first direction R1 is stabilized and the bad connection between the first connector 18 and the second connector 25 can be suppressed. The receiver 144 may come into contact with the supporting base 131 in a normal state, or it may be separated from the supporting base 131 in a normal state and come into contact with the supporting base 131 when a load is applied.

As shown in FIG. 45, the board 133 includes a ground portion 145 in a region in which it faces the receiver 144. The ground portion 145 is a conductor which is exposed to the surface of the board 133 and no component is mounted on the ground portion 145. A strong reaction force is likely to be applied from the receiver 144 to a region of the ground portion 145 facing the receiver 144. Even when the ground portion 145 is damaged, it is less likely to have a great effect on the function of the board 133. That is, since the ground portion 145 is provided such that no electronic component is mounted on a region of the ground portion 145 which faces the receiver 144, the reliability of the dock 32 can be improved.

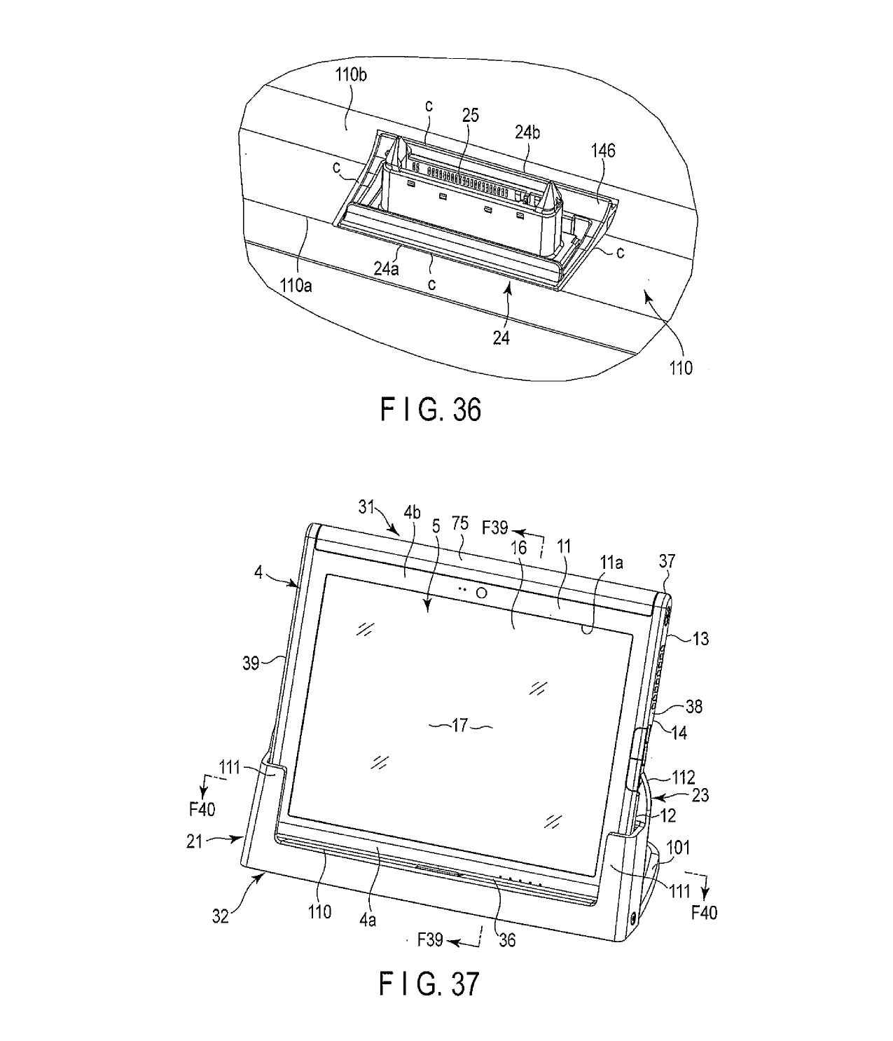

As shown in FIG. 36, the opening 24 of the holder 23 includes a first end 24a and a second end 24b. The first end 24a is, for example, a front end. The second end 24b is opposite to the first end 24a and is, for example, a rear end. The width of the second end 24b is greater than that of the first end 24a. That is, the opening 24 has a wedge shape in which the width thereof increases toward the rear side.

As shown in FIGS. 36 and 42, a guide 146 is provided in the supporting base 131. The guide 146 is provided around the second connector 25 and is supported integrally with the second connector 25 by the supporting portions 132. The guide 146 is smaller than the opening 24 and has substantially the same outward appearance (i.e., a wedge shape) as the opening 24. The guide 146 is inserted into the opening 24 and faces the inner circumferential surface of the opening 24.

A clearance c is provided between the inner circumferential surface of the opening 24 and the guide 146. The second connector 25 can be moved by the clearance c in the opening 24. That is, the inner circumferential surface of the opening 24 and the guide 146 regulate the movement of the second connector 25 in the second direction R2 and the third direction R3. In other words, the second connector 25 can be moved by the clearance c between the inner circumferential surface of the opening 24 and the guide 146 in the second direction R2 and the third direction R3.

The clearance c between the second end 24b of the opening 24 and the guide 146 is greater than the clearance c between the first end 24a of the opening 24 and the guide 146. In this way, the shift amount of the second connector 25 to the rear side can be greater than that of the second connector 25 to the front side.

As shown in FIG. 39, the second direction R2 is substantially perpendicular to the display screen 17, when the electronic apparatus 31 is supported by the holder 23. When the display screen 17 (i.e., touch sensor 16) is operated, the user applies a load to the display screen 17 in the second direction R2. According to this embodiment, when the user applies a load, the electronic apparatus 31 moves back in the second direction R2 to reduce the influence of the load.

As shown in FIG. 46, a conductor 147 is provided in the second housing 21. An example of the conductor 147 is a metal member (e.g., a metal plate) attached to the bottom wall 22. The conductor 147 is electrically connected to the ground of the dock 32. The conductor 147 faces the board 133 from the side opposite to the first connector 18.

A spring 148 is provided between the conductor 147 and the board 133. An example of the spring 148 is a leaf spring, but the spring 148 is not limited thereto. The spring 148 includes a first end 148a and a second end 148b opposite to the first end 148a. The first end 148a extends substantially in parallel to the board 133 and is attached to the board 133. The first end 148a is fixed to the board 133 and is electrically connected to the ground of the board 133.

The second end 148b of the spring 148 extends substantially parallel to the conductor 147 and faces the conductor 147. The second end 148b is not fixed to the conductor 147, but is free with respect to the conductor 147. The second end 148b includes a projection 148c facing the conductor 147. The projection 148c comes into contact with the conductor 147 and is electrically connected to the conductor 147. In this way, the ground of the board 133 is electrically connected to the conductor 147 through the spring 148.

The spring 148 is disposed between the conductor 147 and the board 133 and is compressed between the conductor 147 and the board 133. Therefore, even when the board 133 is moved in a direction in which it is separated from the bottom wall 22, the ground connection between the board 133 and the conductor 147 is maintained by the spring 148. Only the projection 148c of the spring 148 comes into contact with the conductor 147. In this way, the damage of the spring 148 due to friction is suppressed.

(Sound Passage Structure of Dock)

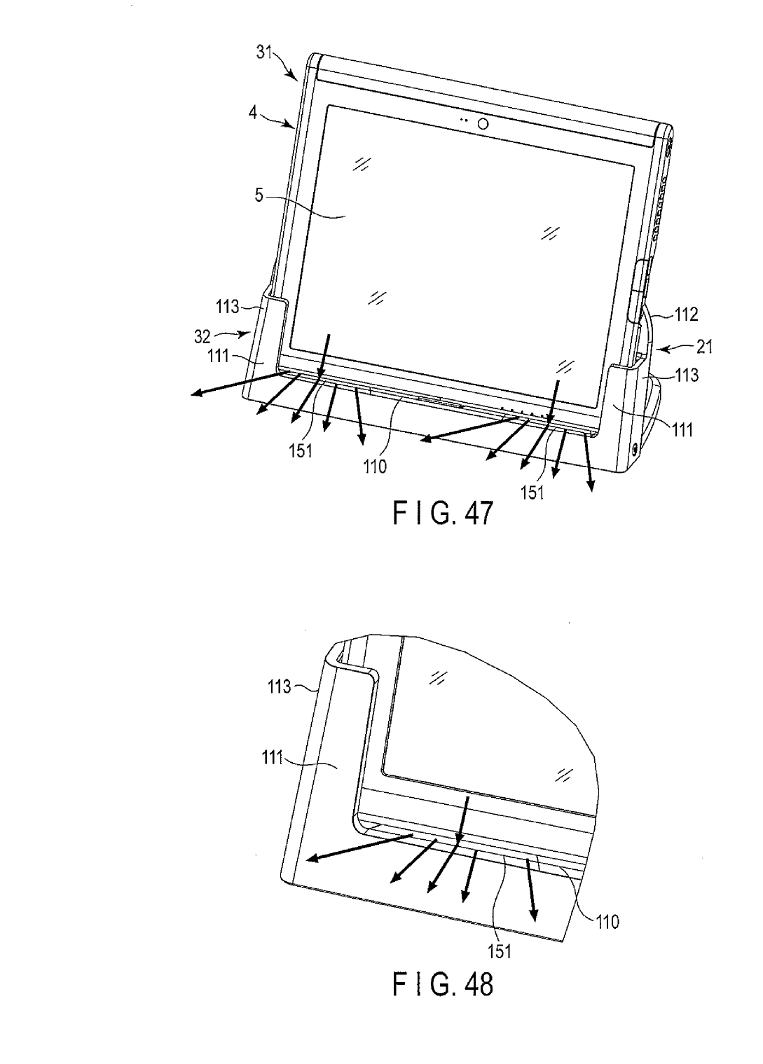

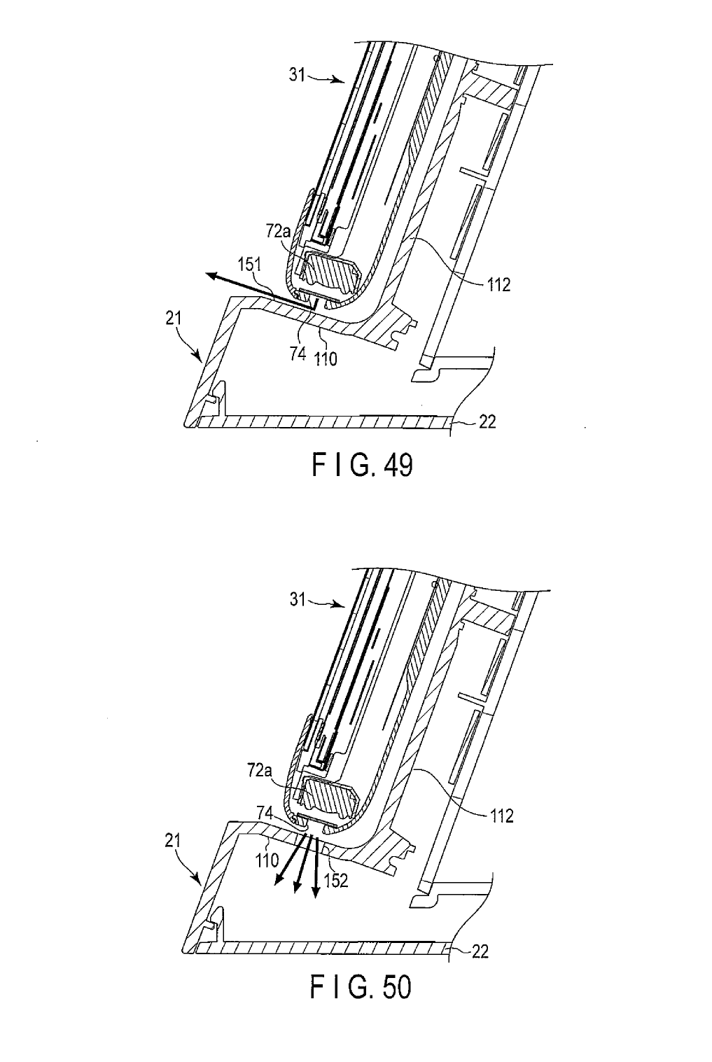

Next, the sound passage structure of the dock 32 will be described with reference to FIGS. 47 to 49. As shown in FIG. 49, the sound holes 74 are provided in the front wall 36 of the electronic apparatus 31. When the electronic apparatus 31 is inserted into the dock 32, the front wall 36 of the electronic apparatus 31 faces the receiving wall 110 of the holder 23.

As shown in FIG. 48, the receiving wall 110 includes a recess 151 (i.e., recessed portion). The recess 151 faces the sound holes 74 of the electronic apparatus 31. The recess 151 is recessed and is lower than other regions of the receiving wall 110. Therefore, the gap through which a sound is released (i.e., emitted) from the sound holes 74 to the outside is formed between the recess 151 and the front wall 36 of the electronic apparatus 31.

FIG. 50 shows a modification of the dock 32. As shown in FIG. 50, the second housing 21 includes an opening 152 through which a sound is released from the sound holes 74 of the electronic apparatus 31 to the outside. In this way, a sound is released from the sound holes 74 of the electronic apparatus 31 to the outside, without being blocked.

According to this structure, the damage to the electronic apparatus 31 and the dock 32 can be suppressed. That is, in this embodiment, the dock 32 includes the holder 23, the connector 25, and the supporting portions 132. The holder 23 can receive the electronic apparatus 31 in the first direction R1 substantially parallel to the display screen 17. The connector 25 is provided in the opening 24 of the holder 23 and is configured to connect to the electronic apparatus 31. A portion of the supporting portion 132 can be elastically deformed in the second direction R2 crossing the first direction R1 and the supporting portion 132 supports the connector 25.

In this way, when the electronic apparatus 31 is inserted into the dock 32, the connector 25 can be appropriately moved and a large load between the electronic apparatus 31 and the dock 32 can be suppressed. Therefore, the damage to the electronic apparatus 31 and the dock 32 can be suppressed.

In this embodiment, the holder 23 can receive the electronic apparatus 31 in the first direction R1 which is inclined with respect to the bottom wall 22. The supporting portion 132 includes the fixing portion 135, the inclined portion 136, and the arm 137. The fixing portion 135 extends substantially in parallel to the bottom wall 22 and is fixed to the second housing 21. The inclined portion 136 is inclined in the first direction R1 with respect to the fixing portion 135. The arm 137 is supported by the inclined portion 136, is inclined in the first direction R1, is curved in a zigzag so as to be elastically deformed in the second direction R2 and the third direction R3 crossing the first direction R1, and supports the connector 25 so as to be movable in the second direction R2 and the third direction R3.

In this way, the supporting portion 132 can support the connector 25 so as to be movable in all directions in the plane which is substantially perpendicular to the insertion/removal direction (i.e., first direction R1) of the connector 25. In addition, it is easy to determine the default position of the connector 25.

In this embodiment, the range in which the connector 25 can be moved is regulated by the inner circumferential surface of the opening 24 and the guide 146. Therefore, the excessive movement of the connector 25 can be suppressed and thus a large load may not be applied to the supporting portion 132.

The embodiments are not limited to the above-described embodiment, but the components according to the above-described embodiment may be changed without departing from the scope and spirit of the invention. In addition, a plurality of components according to the above-described embodiment may be appropriately combined with each other to form various structures. For example, some of the components according to the above-described embodiment may be removed. Components according to different embodiments may be appropriately combined with each other.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A television comprising:
a display comprising a touch sensor;
a housing comprising the display, a first bottom wall, a second bottom wall, a slope, a wall portion, and a side wall,
wherein the first bottom wall is substantially parallel to the display at a first distance from the display, the first bottom wall comprising a first leg,
the second bottom wall is substantially parallel to the display at a second distance greater than the first distance from the display, the second bottom wall comprising a second leg,
the slope is between the first bottom wall and the second bottom wall,
the wall portion is opposite to the first bottom wall and the second bottom wall, the wall portion comprising an opening configured to expose the display,
and the side wall comprises a hole;
a board comprising a portion between the display and the second bottom wall, the board electrically connected to the display;
a heat-generating component on the board between the display and the second bottom wall;
a heat sink facing the hole, the heat sink thermally connected to the heat-generating component; and
a fan between the display and the second bottom wall and configured to blow air to the heat sink.

2. The television of claim 1,
wherein the second leg is higher than the first leg.

3. The television of claim 1,
wherein the first bottom wall and the second bottom wall are configured to incline with respect to an outer mounting surface and to be separated from the surface when the first leg and the second leg are on the surface,
the second bottom wall comprises a first air inlet, and
the slope comprises a second air inlet.

4. The television of claim 3,
wherein the heat-generating component is between the first air inlet and the fan in a first direction crossing a second direction, the second direction extending from the second bottom wall to the first bottom wall.

5. The television of claim 4, further comprising:
an airflow shield between the first bottom wall and the second bottom wall, the airflow shield extending in the first direction and at least partially partitioning the housing into a first region and a second region, the first region comprising the first bottom wall and the second region comprising the second bottom wall, the hole, the fan, the heat-generating component, and the first air inlet.

6. The television of claim 4, further comprising:
a module between the display and the second bottom wall,
wherein the fan and the module are separately on each side of the board in the first direction, and
the first air inlet faces the module.

7. The television of claim 4,
wherein the second bottom wall comprises a third air inlet facing the fan.

8. The television of claim 1,
wherein the housing comprises a first end and a second end, the first end comprising a portion of the first bottom wall and the second end comprising a portion of the second bottom wall,
the opening comprises a first edge along the first end and a second edge along the second end, and
at least a portion of the second leg is further away from the first leg than the second edge.

9. The television of claim 8, further comprising:
a battery removably attached to the second end,
wherein the battery has a thickness substantially equal to that of the second end and a portion of the battery is on a same plane as a portion of the display in a direction from the first bottom wall to the second bottom wall.

10. An electronic apparatus comprising:
a display comprising an input receiving portion; and
a housing comprising the display, a first bottom wall, a second bottom wall, and a slope, wherein the first bottom wall is substantially parallel to the display at a first distance from the display, the second bottom wall is substantially parallel to the display at a second distance greater than the first distance from the display, and the slope is between the first bottom wall and the second bottom wall.

11. An electronic apparatus comprising:
a housing comprising a first end, a second end, and a wall between the first end and the second end, wherein the second end is thicker than the first end and the wall comprises an opening; and
a display in the housing, the display comprising an input receiving portion and exposed through the opening.
